(19) United States
(12) Patent Application Publication
(10) Pub. No.: US 2006/0054919 A1
(43) Pub. Date: Mar. 16, 2006

(54) Light-emitting element, method for manufacturing the same and lighting equipment using the same

(75) Inventors: Toshiya Matsuda, Soraku-gun (JP); Takanori Yasuda, Soraku-gun (JP); Kazuhiro Nishizono, Soraku-gun (JP); Shun Takanami, Soraku-gun (JP); Yuuji Kishida, Soraku-gun (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/213,350

(22) Filed: Aug. 26, 2005

(30) Foreign Application Priority Data
Aug. 27, 2004 (JP) 2004-249081
Sep. 15, 2004 (JP) 2004-267995

(51) Int. Cl. H01L 33/00

(52) U.S. Cl. 257/103

(57) ABSTRACT

The present invention is a light-emitting element provided with semiconductor layers of gallium nitride compounds 4 having a multilayer structure including an emitting layer 3 formed by subjecting gallium nitride compounds to epitaxial growth on a surface 2 of a substrate 1, wherein a back surface 7 of the semiconductor layers 4 exposed by removal of the substrate 1 or an outermost layer 5 of the semiconductor layers 4 is provided as a radiating surface 8 for radiating light emitted from the emitting layer 3 to the outside, and able to provide a higher emission intensity from smaller electrical power because the absence of a substrate greatly improves the radiation efficiency of light.

### BACKGROUND ART OF THE INVENTION

The present invention relates to, for example, a light-emitting element (light-emitting diode: LED) which is used in lighting equipment and the like and having two or more times the energy efficiency ratio than a fluorescent lamp, a method for manufacturing the light-emitting element and lighting equipment using the light-emitting element.

Light-emitting elements in which gallium nitride compounds semiconductor is used are widely known as light-emitting elements which emit from blue to ultraviolet light having a wavelength of approximately 350 to 400 nm. Light-emitting elements in which a gallium nitride compounds semiconductor is used have been disclosed in the following Patent Documents, for example.
(1) JP-A-02-42770 (1990)
(2) JP-A-02-257679 (1990)
(3) JP-A-05-183189 (1993)
(4) JP-A-06-196757 (1994)
(5) JP-A-06-268257 (1994)

In light-emitting elements, it is important that light generated inside the light-emitting element be allowed to radiate to the outside as efficiently as possible, in other words, that radiation efficiency of light be improved. Particularly, in the case of light-emitting elements to be used for lighting equipment, commercialization of which has been recently advanced, improvement in radiation efficiency is indispensable to improvement in the energy efficiency ratio.

The following three elements are exemplified as a light-emitting element which has been improved in structure for emitting light in order to improve the light-emitting efficiency. The first example is a light-emitting element, in which the outermost surface of semiconductor layers intersecting with the lamination direction of gallium nitride compounds which is formed on a surface of a substrate, having a multilayer structure, or an outer surface of a translucent conductive layer formed on the outermost surface is provided as a light radiating surface and a reflection layer is provided on the surface of the substrate which is opposite the radiating surface. Light-emitting elements having the structure have been disclosed in the following Patent Documents, for example.
(6) JP-A-08-102549 (1996)
(7) JP-A-11-126925 (1999)
(8) JP-A-2001-7392
(9) JP-A-2001-7397

FIG. 27 is a sectional view showing an example of the layer constitution of the light-emitting element. With reference to FIG. 27, the light-emitting element shown in the figure is provided with a substrate 101, semiconductor layers of gallium nitride compounds (hereinafter also referred to as a “semiconductor layers”) 104 formed by subjecting gallium nitride compounds to epitaxial growth on a surface 102 of the substrate 101 and having a multilayer structure including an emitting layer 103, a translucent conductive layer 106 having electrical conductivity and transmitting light emitted from the emitting layer 103 which is formed on the outermost surface 105 of the semiconductor layers 104 intersecting with the lamination direction in a state of being electrically connected, and an electrode pad 108 of the translucent conductive layer 106 connected partially to an outer surface 107 which is opposite a surface contacting with the semiconductor layers 104, wherein the outer surface 107 of the translucent conductive layer 106 is given as a radiating surface for emitting the light to the outside. The semiconductor layers 104 are constituted by sequentially laminating a first conductive-type semiconductor layer 109, the emitting layer 103 and a second conductive-type semiconductor layer 110 on the surface 102 of the substrate 101.

A surface 111 of the first conductive-type semiconductor layer 109 intersecting with the lamination direction is partially exposed by a partial removal of the emitting layer 103 and the second conductive-type semiconductor layer 110, and an electrode pad 112 is connected to the exposed surface 111. A reflection layer 114 for reflecting light emitted from the emitting layer 103 is provided on the surface 113 of the substrate 101 which is opposite the surface 102 of the semiconductor layers 104 are formed.

In the light-emitting element, when electricity is allowed to flow between electrode pads 108 and 112, hole and electron (or electron and hole) injected into the semiconductor layers 104 from both the electrode pads 108 and 112 are transported respectively to the second conductive-type semiconductor layer 110 and the first conductive-type semiconductor layer 109 in the thickness direction and recombined in the emitting layer 103, by which gallium nitride compounds constituting the emitting layer 103 are excited to emit light.

Then, as shown by the arrow of the dashed line in the figure, light heading from the emitting layer 103 for the outermost surface 105 of the semiconductor layers 104 passes through the second conductive-type semiconductor layer 110 and the translucent conductive layer 106 and is directly radiated to the outside of the light-emitting element from the outer surface 107. Further, light heading from the emitting layer 103 for the substrate 101 passes through the first conductive-type semiconductor layer 109 and the substrate 101, and is reflected on the opposite surface 113 of the substrate 101 which is the boundary face between the substrate 101 and the reflection layer 114. Further, the reflected light passes through the substrate 101, the first conductive-type semiconductor layer 109, the emitting layer 103, the second conductive-type semiconductor layer 110 and the translucent conductive layer 106, and then radiated to outside of the light-emitting element from the outer surface 107.

The second example is a light-emitting element wherein a reflection layer is provided on a surface of a substrate which forms semiconductor layers of gallium nitride compounds, the semiconductor layers are laminated thereon and a reflection layer on the opposite surface of the substrate is omitted. Light-emitting elements with the structure are disclosed in the following Patent Documents, for example.
(10) JP-A-03-108778 (1991)
(11) JP-A-03-163882 (1991)
(12) JP-A-09-232631 (1997)
(13) JP-A-11-251642 (1999)
(14) JP-A-11-274568 (1999)
(15) JP-A-2001-168387
(16) JP-A-2004-31405

FIG. 28 is a sectional view showing one example of the layer constitution of the light-emitting element. With reference to FIG. 28, the light-emitting element shown in the figure is provided with a substrate 101, a reflection layer 115 formed on the surface 102 of the substrate 101, semiconductor layers of gallium nitride compounds 104 having a multilayer structure including an emitting layer 103 which are formed by subjecting gallium nitride compounds to epitaxial growth on the reflection layer 115, a translucent conductive layer 106 formed on the outermost surface 105 of the semiconductor layer 104 intersecting with the lamination direction in a state of being electrically connected and an electrode pad 108 connected partially to an outer surface 107 of the translucent conductive layer 106 which is opposite a surface contacting with the semiconductor layers 104, wherein the outer surface 107 of the translucent conductive layer 106 is provided as a radiating surface for radiating the light to the outside.

The semiconductor layers 104 are constituted by sequentially laminating the first conductive-type semiconductor layer 109, the emitting layer 103 and the second conductive-type semiconductor layer 110 on the reflection layer 115. The surface 111 of the first conductive-type semiconductor layer 109 intersecting with the lamination direction is partially exposed by a partial removal of the emitting layer 103 and the second conductive-type semiconductor layer 110, and the electrode pad 112 is connected to the exposed surface 111.

In the light-emitting element, when electricity is allowed to flow between electrode pads 108 and 112, hole and electron (or electron and hole) injected into the semiconductor layers 104 from both the electrode pads 108 and 112 are transported respectively to the second conductive-type semiconductor layer 110 and the first conductive-type semiconductor layer 109 in the thickness direction and recombined in the emitting layer 103, by which gallium nitride compounds constituting the emitting layer 103 are excited to emit light.

Then, as shown by the arrow of the dashed line in the figure, light heading from the emitting layer 103 for the outermost surface 105 of the semiconductor layers 104 passes through the second conductive-type semiconductor layer 110 and the translucent conductive layer 106, and is directly radiated to the outside of the light-emitting element from the outer surface 107. Further, light heading from the emitting layer 103 for the substrate 101 passes through the first conductive-type semiconductor layer 109, reaching the reflection layer 115, and is reflected inside the reflection layer 115 or on a boundary face between the first conductive-type semiconductor layer 109 and the reflection layer 115. Further, the reflected light passes through the first conductive-type semiconductor layer 109, the emitting layer 103, the second conductive-type semiconductor layer 110 and the translucent conductive layer 106, and is radiated to the outside of the light-emitting element from the outer surface 107.

The third example is a light-emitting element, wherein a reflection layer is provided on the outermost surface of semiconductor layers intersecting with the lamination direction of gallium nitride compounds formed on the surface of the substrate and having a multilayer structure, and the surface of the substrate which is opposite the foregoing surface is provided as a radiating surface. Light-emitting elements having the structure are disclosed in the following Patent Documents, for example.
(17) JP-A-10-144961 (1998)
(18) JP-A-11-220168 (1999)
(19) JP-A-11-261109 (1999)
(20) JP-A-2000-31540
(21) JP-A-2000-183400
(22) JP-A-2000-294837
(23) JP-A-2002-246649
(24) JP-A-2003-532298
(25) JP-U-3068914

FIG. 29 is a sectional view showing one example of the layer constitution of the light-emitting element. With reference to FIG. 29, the light-emitting element shown in the figure is provided with a substrate 101, semiconductor layers of gallium nitride compounds 104 having a multilayer structure including an emitting layer 103 which are formed by subjecting gallium nitride compounds to epitaxial growth on the surface 102 of the substrate 101, and a conductive reflection layer 116 having electrical conductivity and reflecting light emitted from the emitting layer 103 which is formed on the outermost surface 105 of the semiconductor layers 104 intersecting with the lamination direction in a state of being electrically connected.

The semiconductor layers 104 are constituted by sequentially laminating the first conductive-type semiconductor layer 109, the emitting layer 103 and the second conductive-type semiconductor layer 110 on the surface 102 of the substrate 101. The surface 111 of the first conductive-type semiconductor layer 109 intersecting with the lamination direction is partially exposed by a partial removal of the emitting layer 103 and the second conductive-type semiconductor layer 110, and the electrode pad 112 is connected to the thus exposed surface 111. The surface 113 of the substrate 101 opposite the surface 102 on which the semiconductor layers 104 are formed is provided as a radiating surface for radiating outside the light emitted from the emitting layer 103.

In the light-emitting element, when electricity is allowed to flow between a conductive reflection layer 116 and an electrode pad 112, hole and electron (or electron and hole) injected into the semiconductor layers 104 from both sides are transported respectively to the second conductive-type semiconductor layer 110 and the first conductive-type semiconductor layer 109 in the thickness direction and recombined in the emitting layer 103, by which gallium nitride compounds constituting the emitting layer 103 are excited to emit light.

Then, as shown by the arrow of the dashed line in the figure, light heading from the emitting layer 103 for the substrate 101 passes through the first conductive-type semiconductor layer 109 and the substrate 101, and is directly radiated to the outside of the light-emitting element from the opposite surface 113. Further, light heading from the emitting layer 103 for the outermost surface 105 of the semiconductor layers 104 passes through the second conductive-type semiconductor layer 110, reaching the outermost surface 105 of the semiconductor layers 104 which is a boundary face between the second conductive-type semiconductor layer 110 and the conductive reflection layer 116, and is reflected on the outermost surface 105. Further, the reflected light passes through the second conductive-type semiconductor layer 110, the emitting layer 103, the first conductive-type semiconductor layer 109 and the substrate 101, and is radiated to the outside of the light-emitting element from the opposite surface 113.

In the light-emitting element of FIG. 27, light heading from the emitting layer 103 for the substrate 101 is easily absorbed by the substrate 101 while transmitting through the substrate 101, and a part of the light reflected on the opposite surface 113 of the substrate 101 is reflected repeatedly between the surface 102 of the substrate 101 which is a boundary face between the substrate 101 and the first conductive-type semiconductor layer 109 and the opposite surface 113, thereby being confined inside the substrate 101 and being attenuated. Therefore, such problems exist that even when a reflection layer 114 is provided to improve the reflectance ratio of light on the opposite surface 113, radiation efficiency of light emitted from the outer surface 107 is not improved as expected, as compared with a case where the reflection layer 114 is not provided.

The same applies to the light-emitting element of FIG. 29, namely, light heading directly from the reflected emitting layer 103 for the substrate 101 or after reflection by the conductive reflection layer 116 is easily absorbed in the substrate 101 while transmitted through the substrate 101, and a part of the light is repeatedly reflected between the surface 102 of the substrate 101 and the opposite surface 113, thereby being confined inside the substrate 101 and being attenuated. Thus, problems are posed that even when a conductive reflection layer 116 is provided to reflect the light, radiation efficiency of the light emitted from the opposite surface 113 is not improved as expected, as compared with a case where the conductive reflection layer 116 is not provided.

The light-emitting element of FIG. 28 in which light from the emitting layer 103 does not pass through the substrate 101 will not pose problems that the light is absorbed by the substrate 101 or attenuated. However, there are restrictions on materials and structures of the reflection layer 115 which are able to subject semiconductor layers of gallium nitride compounds 104 excellent in crystalline quality to epitaxial growth on the reflection layer 115. Further, reflection layers 115 having these materials and structures are in most cases low in the reflectance ratio of light or restricted in the wavelength of light that can be reflected, therefore, a problem exists that a high reflectance ratio is not obtained even in combination with the semiconductor layers 104 emitting from blue to ultraviolet light. Therefore, there are problems that even when a reflection layer 115 is provided to reflect light, radiation efficiency of the light emitted from the opposite surface 113 is not improved as expected, as compared with a case where the reflection layer 115 is not provided.

### DISCLOSURE OF THE INVENTION

An object of the present invention is to provide a high performance light-emitting element capable of giving a higher emission intensity from smaller electrical power as a result of a great improvement in radiation efficiency of light. Another object of the present invention is to provide a method for manufacturing the light-emitting element efficiently and at a higher productivity. Still another object of the present invention is to provide lighting equipment excellent in an energy efficiency ratio by using the light-emitting element.

The light-emitting element of the present invention comprising; semiconductor layers of gallium nitride compounds having a multilayer structure including an emitting layer which are formed by subjecting gallium nitride compounds to epitaxial growth on a substrate; a conductive reflection layer having electrical conductivity and reflecting light emitted from the emitting layer which is formed on the outermost surface of the semiconductor layers intersecting with the lamination direction in a state of being electrically connected; and a conductive layer electrically connected to a layer constituting a back surface of the semiconductor layers contacting with the substrate, wherein the back surface is exposed by removal of the substrate and provided as a radiating surface for radiating light emitted from the emitting layer to the outside of the semiconductor layers.

In the light-emitting element of the present invention, the back surface of the semiconductor layers of gallium nitride compounds from which the substrate is removed is given as a surface of radiating light emitted from the emitting layer, thus making it possible to radiate the light to the outside from the radiating surface, without passage through the substrate, thereby solving problems such as absorption and attenuation of light by the substrate.

Further, as explained previously, the substrate is not involved in transmission of light, thereby removing the necessity for considering translucency and the like. Therefore, a substrate which is in conformity with semiconductor layers of gallium nitride compounds in a lattice constant and capable of forming the semiconductor layers of gallium nitride compounds excellent in crystalline quality and light-emitting efficiency on the surface by being subjected to epitaxial growth is selectively used as the substrate, making it possible to improve the light-emitting efficiency of the semiconductor layers thus formed.

In addition, the conductive reflection layer is subsequently provided on the outermost surface of the semiconductor layers formed by being subjected to epitaxial growth and not restricted in materials, structures and others. Therefore, a conductive reflection layer provided with electrical conductivity and excellent in the reflectance ratio of from blue to ultraviolet light in a wavelength of approximately 350 to 400 nm, in particular, can be selectively used as the conductive reflection layer, making it possible to improve the reflectance ratio of light of the conductive reflection layer.

Therefore, according to the light-emitting element of the present invention, light emitted from the emitting layer and radiated to the outside from the radiating surface is greatly improved in radiation efficiency due to connection of the individual effects, thereby making it possible to obtain a higher emission intensity from smaller electrical power.

In the light-emitting element of the present invention, where an anti-reflection layer is formed on the back surface of the semiconductor layers by removal of the substrate as a radiating surface, it is possible to reduce the reflectance ratio of light on the radiating surface, improve the transmittance and prevent the light from being repeatedly reflected in the semiconductor layers. It is, therefore, possible to further improve the radiation efficiency of light radiated from the emitting layer to the outside of the radiating surface.

When consideration is given to an additional increase in transmittance of light on the radiating surface, the anti-reflection layer is preferable whose refractive index is simply decreased from a surface contacting with the semiconductor layers to an outer surface which is opposite the surface. It is also preferable that the thickness of the anti-reflection layer is formed one-quarter of the wavelength of light emitted from the emitting layer in the anti-reflection layer.

In addition, in the light-emitting element of the present invention, where many projections are formed on the back surface of the semiconductor layers as a radiating surface or on the outer surface of the anti-reflection layer formed on the back surface and the dimension of the projection in the direction intersecting with the height direction is simply decreased from the base of the projection to the apex, them any projections function to reduce the reflectance ratio of light on any of the surfaces, thereby making it possible to improve the transmittance.

In other words, when many projections are formed on any of the surfaces, the surface is given a predetermined three-dimensional configuration in relation to a flat surface intersecting with the lamination direction of the semiconductor layers to form an aggregate of surfaces having many inclined projections. Therefore, of light emitted from the emitting layer and entering into the surface, a ratio of components totally reflected due to an incidence angle which exceeds a critical angle established by a boundary face between the semiconductor layers and air, a boundary face between the semiconductor layers and the anti-reflection layer or a boundary face between the anti-reflection layer and air can be decreased as compared with a case where the surface is a flat surface, thereby making it possible to decrease the reflectance ratio of light on the surface and improve the transmittance. Therefore, it is possible to decrease the reflectance ratio of light on the radiating surface of the light-emitting element, improve the transmittance and further improve the radiation efficiency of light radiated from the emitting layer to the outside of the radiating surface.

When consideration is given to a further increase in transmittance of light on the radiating surface, it is preferable that the dimension of the base of the projection in the direction intersecting with the height direction is not more than one time the wavelength of light emitted from the emitting layer in the layer forming the projections and also the height of the projection is not less than one time the wavelength.

Further, in the light-emitting element of the present invention, many recesses are provided on the back surface of the semiconductor layers or on the outer surface of the anti-reflection layer formed on the back surface and the dimension of the recess in the direction intersecting with the depth direction is simply decreased from the opening to the bottom of the recess, these many recesses function to decrease the reflectance ratio of light on any of the surfaces, thereby making it possible to improve the transmittance.

In other words, when many recesses are provided on any of the surfaces, the surface is given in a predetermined three-dimensional configuration in relation to a flat surface intersecting with the lamination direction of the semiconductor layers and consequently formed by an aggregate of surfaces having many inclined recesses. Therefore, of light emitted from the emitting layer and entering into the surface, a ratio of components totally reflected due to an incidence angle which exceeds a critical angle established by a boundary face between the semiconductor layers and air, a boundary face between the semiconductor layers and the anti-reflection layer or a boundary face between the anti-reflection layer and air can be decreased as compared with a case where the surface is a flat surface, thereby making it possible to decrease the reflectance ratio of light on the surface and improve the transmittance. Therefore, it is possible to decrease the reflectance ratio of light on the radiating surface of the light-emitting element, improve the transmittance and further improve the radiation efficiency of light radiated from the emitting layer to the outside of the radiating surface.

When consideration is given to a further increase in transmittance of light on the radiating surface, it is preferable that the dimension of the opening of the recess in the direction intersecting with the depth direction is not more than one time the wavelength of light emitted from the emitting layer in the layer forming the recess and also the depth of the recess is not less than one time the wavelength.

It is preferable that the conductive reflection layer is formed of aluminum or silver provided with electrical conductivity and also excellent in the reflectance ratio of from blue to ultraviolet light in particular.

It is preferable that a bump electrode is connected to the outer surface of the conductive reflection layer which is opposite a surface contacting with the semiconductor layers. In a conventional light-emitting element provided with a substrate and semiconductor layers of gallium nitride compounds, when the light-emitting element is subjected to flip chip mounting on a package or the like via a bump electrode, heating in this instance applies stress to semiconductor layers on the basis of a difference in the coefficient of thermal expansion between the matters, resulting in detachment of an area from the substrate or distortion of the semiconductor layers, thereby affecting the reliability of the light-emitting element. In contrast, in the light-emitting element of the present invention, a substrate is removed and stress applied to semiconductor layers due to heat generated while subjecting the light-emitting element to flip chip mounting can be decreased as compared with a conventional light-emitting element, thereby making it possible to decrease distortion of the semiconductor layers and improve the reliability of the light-emitting element.

In order to manufacture the light-emitting element of the present invention, a method for manufacturing the light-emitting element of the present invention comprises; a step of forming semiconductor layers by being subjected to epitaxial growth on a substrate; a step of forming a conductive reflection layer on the outermost surface of the semiconductor layers; and a step of exposing the back surface of the semiconductor layers by removal of the substrate in a state that the semiconductor layers and the conductive reflection layer are covered with a protective layer.

According to the manufacturing method of the present invention, the conductive reflection layer and the semiconductor layers thereunder are covered with the protective layer in the step of removing the substrate, thereby making it possible to prevent contamination or corrosion of these layers, for example, by an etching solution and the like for removing the substrate. Further, since the conductive reflection layer and the semiconductor layers can be mechanically reinforced by a protective layer, these layers can be prevented from being distorted by stress. Therefore, the manufacturing method of the present invention makes it possible to a prevent reduction in yield due to various defects such as the previously-described contamination, corrosion and distortion, thereby manufacturing the light-emitting element of the present invention more efficiently and at a higher productivity.

Further, when the back surface of the semiconductor layers exposed by removal of the substrate is subjected to anti-reflection treatment according to the manufacturing method of the present invention, as explained previously, the radiation efficiency of light emitted from the emitting layer and radiated to the outside of the radiating surface can be further improved.

In addition, when a bump electrode is connected to the outer surface of the conductive reflection layer after the conductive reflection layer is formed before the substrate is removed and the substrate is removed in a state that the semiconductor layers, the conductive reflection layer and the bump electrode are covered with a protective layer, a decreased yield due to defects such as contamination and corrosion of the bump electrode by an etching solution and the like for removing the substrate can be prevented, thereby making it possible to manufacture the light-emitting element of the present invention more efficiently and at a higher productivity.

When the bump electrode is connected to the outer surface of the conductive reflection layer after the substrate is removed to expose the back surface of the semiconductor layers, a decreased yield due to defects such as contamination, corrosion and stress-related deterioration of the bump electrode by an etching solution and the like for removing the substrate can be prevented, thereby making it possible to manufacture the light-emitting element of the present invention more efficiently and at a higher productivity.

It is preferable that the substrate is in conformity with semiconductor layers of gallium nitride compounds in a lattice constant and formed by boride monocrystal capable of forming the semiconductor layers of gallium nitride compounds excellent in crystalline quality and light-emitting efficiency on the surface by being subjected to epitaxial growth. Preferable are monocrystals of zirconium boride or titanium boride as the boride monocrystal.

In the lighting equipment of the present invention, the light-emitting element of the present invention is constituted in combination with at least either a fluorescent material or a phosphorescent material, and therefore excellent in the energy efficiency ratio.

The light-emitting element of the present invention comprising; semiconductor layers of gallium nitride compounds having a multilayer structure including an emitting layer formed by subjecting gallium nitride compounds to epitaxial growth on a substrate; a translucent conductive layer having electrical conductivity and transmitting light emitted from the emitting layer which is formed on an outermost surface of the semiconductor layers intersecting with the lamination direction in a state of being electrically connected; and a conductive layer electrically connected to a layer constituting the back surface of the semiconductor layers contacting with the substrate; wherein the back surface is exposed by removal of the substrate, a reflection layer for reflecting light emitted from the emitting layer is formed on the exposed back surface, and the outer surface of the translucent conductive layer which is opposite a surface contacting with the semiconductor layers is provided as a radiating surface for radiating light emitted from the emitting layer to the outside of the semiconductor layers.

In the light-emitting element of the present invention, the reflection layer for reflecting light emitted from an emitting layer is formed on the back surface of the semiconductor layers of gallium nitride compounds from which the substrate is removed, thus making it possible to radiate the light to the outside from the radiating surface which is the outer surface of the translucent conductive layer formed on the outermost surface of the semiconductor layers, without passage through the substrate, thereby solving problems such as absorption and attenuation of light by the substrate.

Further, as explained previously, the substrate is not involved in transmission of light, thereby removing the necessity for considering translucency and the like. Therefore, a substrate which is in conformity with semiconductor layers of gallium nitride compounds in a lattice constant and capable of forming the semiconductor layers of gallium nitride compounds excellent in crystalline quality and light-emitting efficiency on the surface by being subjected to epitaxial growth is selectively used as the substrate, thus making it possible to improve the light-emitting efficiency of the semiconductor layers thus formed.

Further, the reflection layer is subsequently formed on the back surface of the semiconductor layers exposed by removal of the substrate after formed by being subjected to epitaxial growth and not restricted in materials, structures and others. Therefore, a reflection layer excellent in the reflectance ratio of from blue to ultraviolet light, in particular, can be used selectively as the reflection layer, and the reflectance ratio of light can also be improved in the reflection layer.

Therefore, according to the light-emitting element of the present invention, light emitted from the emitting layer and radiated to the outside from the radiating surface is greatly improved in radiation efficiency due to connection of the individual effects, thereby making it possible to obtain a higher emission intensity from smaller electrical power.

The reflection layer is preferably formed of titanium, aluminum or silver excellent in the reflectance ratio of from blue to ultraviolet light in particular.

It is also preferable that a support is joined on an outer surface of the reflection layer. When the support is joined on the outer surface of the reflection layer, semiconductor layers of gallium nitride compounds can be reinforced by the support, thereby making it possible to improve the strength of a light-emitting element and facilitate the handling of the element. For example, the support is used as a base for the light-emitting element, by which the light-emitting element can be reliably mounted into packages and the like. Further, the support is subsequently joined after formation of the reflection layer by removal of the substrate and not restricted in materials, structures and others. Thus, a support which is close to the semiconductor layers in the coefficient of thermal expansion and excellent in desired characteristics such as heat conduction characteristics, electrical conduction characteristics and mechanical characteristics can be used selectively as the support to improve the reliability of the light-emitting element. The support is preferably formed of silicon excellent in the above-described respective characteristics.

In the light-emitting element of the present invention, where an anti-reflection layer is formed between the outermost surface of the semiconductor layers and the translucent conductive layer or on the outer surface of the translucent conductive layer, the reflectance ratio of light on any of the surfaces is decreased to improve the transmittance, thereby making it possible to prevent the light from being repeatedly reflected in the semiconductor layers. Therefore, the radiation efficiency of light emitted from the emitting layer and radiated to the outside from the radiating surface, which is an outer surface of the translucent conductive layer, can be further improved.

Further, with consideration given to a further increase in transmittance of light on the radiating surface, where an anti-reflection layer is formed between the outermost surface of the semiconductor layers and the translucent conductive layer, it is preferable that the refractive index of the anti-reflection layer is simply decreased from the surface contacting with the semiconductor layers to the surface contacting with the translucent conductive layer. Where the anti-reflection layer is formed on the outer surface of the translucent conductive layer, it is preferable that the refractive index of the anti-reflection layer is simply decreased from the surface contacting with the translucent conductive layer to the outer surface opposite the surface. It is also preferable that the thickness of the anti-reflection layer is formed one-quarter of the wavelength of light emitted from the emitting layer in the anti-reflection layer.

Where many projections are formed on the outermost surface of the semiconductor layers or the outer surface of the anti-reflection layer and the dimension of the projection in the direction intersecting with the height direction is simply decreased from the base of the projection to the apex, the previously-described many projections function to decrease the reflectance ratio of light on any of the surfaces, thereby making it possible to improve the transmittance. Therefore, the reflectance ratio of light emitted from the light-emitting element on the radiating surface is decreased to improve the transmittance, by which the radiation efficiency of light emitted from the emitting layer and radiated to the outside from the radiating surface can be further improved.

When consideration is given to a further increase in the radiation efficiency of light on the radiating surface, it is preferable that the dimension of the base of the projection in the direction intersecting with the height direction is not more than one time the wavelength of light emitted from the emitting layer in the layer on which the projections are formed and also the height of the projection is not less than one time the wavelength.

Where many recesses are formed on the outermost surface of the semiconductor layers or the outer surface of the anti-reflection layer and the dimension of the recess in the direction intersecting with the depth direction is simply decreased from an opening of the recess to a bottom, the previously-described many recesses function to decrease the reflectance ratio of light on any of the surfaces, thereby making it possible to improve the transmittance. Therefore, the reflectance ratio of light emitted from the light-emitting element on the radiating surface is decreased to improve the transmittance, by which the radiation efficiency of light emitted from the emitting layer and radiated to the outside from the radiating surface can be further improved.

When consideration is given to a further increase in the radiation efficiency of light on the radiating surface due to the recesses, it is preferable that the dimension of the opening of the recess in the direction intersecting with the depth direction is not more than one time the wavelength of light emitted from the emitting layer in the layer on which the recesses are formed and also the depth of the recess is not less than one time the wavelength.

Where the translucent conductive layer is provided in a flat surface form having a through hole and the outermost surface of the semiconductor layers exposed at the through hole is also provided as a radiating surface for radiating light emitted from the emitting layer to the outside of the semiconductor layers, a decreased transmittance of light by the translucent conductive layer can be prevented, thereby making it possible to further improve the radiation efficiency of light emitted from the emitting layer and radiated to the outside from the radiating surface.

In order to manufacture the light-emitting element of the present invention, a method for manufacturing the light-emitting element of the present invention comprises; a step of forming semiconductor layers by being subjected to epitaxial growth on a substrate; a step of forming a translucent conductive layer on the outermost surface of the semiconductor layers; and a step of exposing the back surface of the semiconductor layers by removal of the substrate in a state that the semiconductor layers and the translucent conductive layer are covered with a protective layer.

According to the manufacturing method of the present invention, the translucent conductive layer and the semiconductor layers thereunder are covered with a protective layer in the step of removing the substrate, thereby making it possible to prevent contamination or corrosion of these layers by an etching solution and the like for removing the substrate, for example. Further, since the translucent conductive layer and the semiconductor layers can be mechanically reinforced by the protective layer, these layers can be prevented from being distorted by stress. Therefore, the manufacturing method of the present invention makes it possible to prevent a reduction in yield due to various defects such as the previously-described contamination, corrosion and distortion, thereby manufacturing the light-emitting element of the present invention more efficiently and at a higher productivity.

It is preferable that the substrate is in conformity with semiconductor layers of gallium nitride compounds in a lattice constant and formed by a boride monocrystal capable of forming the semiconductor layers of gallium nitride compounds excellent in crystalline quality and light-emitting efficiency on the surface by being subjected to epitaxial growth. Preferable are monocrystals of zirconium boride or titanium boride as the boride monocrystal.

In the lighting equipment of the present invention, the light-emitting element of the present invention is constituted in combination with at least either a fluorescent material or a phosphorescent material, and therefore excellent in the energy efficiency ratio.

The light-emitting element of the present invention comprising; provided with semiconductor layers of gallium nitride compounds having a multilayer structure including an emitting layer formed by subjecting gallium nitride compounds to epitaxial growth on a substrate; a first conductive layer formed on an outermost surface of the semiconductor layers intersecting with the lamination direction in a state of being electrically connected; and a second conductive layer formed on a back surface of the semiconductor layers exposed by removal of the substrate in a state of being electrically connected; wherein either of the first or the second conductive layer functioning as a conductive reflection layer having electrical conductivity and reflecting light emitted from the emitting layer, and the other layer is functioning as a translucent conductive layer having electrical conductivity and transmitting light emitted from the emitting layer, and the outer surface of the translucent conductive layer which is opposite a surface contacting with the semiconductor layers is provided as a radiating surface for radiating light emitted from the emitting layer outside the semiconductor layers.

In the light-emitting element of the present invention, the second conductive layer is provided on the back surface of the semiconductor layers of gallium nitride compounds from which the substrate is removed, and the light emitted from the emitting layer can be radiated to the outside from the radiating surface which is an outer surface of the translucent conductive layer, of the second conductive layer or the first conductive layer formed on the outermost surface of the semiconductor layers, without passage through the substrate, thus making it possible to solve problems such as absorption and attenuation of light by the substrate.

Further, as described above, the substrate is not involved in transmission of light, thereby removing the necessity for considering translucency and the like. Therefore, the substrate which is in conformity with semiconductor layers of gallium nitride compounds in a lattice constant and capable of forming the semiconductor layers of gallium nitride compounds excellent in crystalline quality and light-emitting efficiency on the surface by being subjected to epitaxial growth is selectively used, thus making it possible to improve the light-emitting efficiency of the semiconductor layers thus formed.

After being formed by epitaxial growth, the conductive layer is formed subsequently on the back surface of the semiconductor layers exposed by removal of the substrate and not restricted in materials, structure and the like. Therefore, where the second conductive layer is a conductive reflection layer, it is provided with electrical conductivity, able to selectively use the conductive reflection layer excellent in the reflectance ratio of from blue to ultraviolet light, in particular, and also to improve the reflectance ratio of light in the conductive reflection layer. Further, where the second conductive layer is a translucent conductive layer, it is provided with electrical conductivity, able to selectively use a translucent conductive layer excellent in transmittance of from blue to ultraviolet light, in particular, and also to improve the transmittance of light in the translucent conductive layer.

Thus, according to the light-emitting element of the present invention, light emitted from the emitting layer and radiated to the outside from the radiating surface is greatly improved in radiation efficiency due to connection of the individual effects, thereby making it possible to obtain a higher emission intensity from smaller electrical power.

It is preferable that the conductive reflection layer is provided with electrical conductivity and formed of aluminum or silver excellent in the reflectance ratio of from blue to ultraviolet light in particular.

It is also preferable that a support is joined on an outer surface of the conductive reflection layer. When the support is joined on the outer surface of the conductive reflection layer, semiconductor layers of gallium nitride compounds can be reinforced by the support, thereby making it possible to improve the strength of a light-emitting element and facilitate the handling of the element. Further, the support is subsequently joined after formation of the conductive reflection layer by removal of the substrate and not restricted in materials, structures and others. Thus, a support which is close to the semiconductor layers in the coefficient of thermal expansion and excellent in desired characteristics such as heat conduction characteristics, electrical conduction characteristics and mechanical characteristics can be used selectively as the support to improve the reliability of the light-emitting element. The support is preferably formed of silicon excellent in the above-described respective characteristics.

In the light-emitting element of the present invention, where an anti-reflection layer is formed between the surface of the semiconductor layers on which the translucent conductive layer is formed and the translucent conductive layer or on the outer surface of the translucent conductive layer, the reflectance ratio of light on any of the surfaces is decreased to improve the transmittance, thereby making it possible to prevent the light from being repeatedly reflected in the semiconductor layers. Therefore, the radiation efficiency of light emitted from the emitting layer and radiated to the outside from the radiating surface, which is an outer surface of the translucent conductive layer, can be further improved.

Further, when consideration is given to a further increase in transmittance of light on the radiating surface, where an anti-reflection layer is formed between the surface of the semiconductor layers on which the translucent conductive layer is formed and the translucent conductive layer, it is preferable that the refractive index of the anti-reflection layer is simply decreased from the surface contacting with the semiconductor layers to the surface contacting with the translucent conductive layer. Where the anti-reflection layer is formed on the outer surface of the translucent conductive layer, it is preferable that the refractive index of the anti-reflection layer is simply decreased from the surface contacting with the translucent conductive layer to the outer surface opposite the surface. It is also preferable that the thickness of the anti-reflection layer is formed one-quarter of the wavelength of light emitted from the emitting layer in the anti-reflection layer.

Where many projections are formed on the surface of the semiconductor layers where the translucent conductive layer is formed or the outer surface of the anti-reflection layer and the dimension of the projection in the direction intersecting with the height direction is simply decreased from the base of the projection to the apex, the previously-described many projections function to decrease the reflectance ratio of light on any of the surfaces, thereby making it possible to improve the transmittance. Therefore, the reflectance ratio of light emitted from the light-emitting element on the radiating surface is decreased to improve the transmittance, by which the radiation efficiency of light emitted from the emitting layer and radiated to the outside from the radiating surface can be further improved.

When consideration is given to a further increase in the radiation efficiency of light on the radiating surface due to the projections, it is preferable that the dimension of the base of the projection in the direction intersecting with the height direction is not more than one time the wavelength of light emitted from the emitting layer in the layer on which the projections are formed and also the height of the projection is not less than one time the wavelength.

Where many recesses are formed on the surface of the semiconductor layers on which the translucent conductive layer is formed or the outer surface of the anti-reflection layer and the dimension of the recess in the direction intersecting with the depth direction is simply decreased from an opening of the recess to a bottom, the previously-described many recesses function to decrease the reflectance ratio of light on any of the surfaces, thereby making it possible to improve the transmittance. Therefore, the reflectance ratio of light emitted from the light-emitting element on the radiating surface is decreased to improve the transmittance, by which the radiation efficiency of light emitted from the emitting layer and radiated to the outside from the radiating surface can be further improved.

When consideration is given to a further increase in the radiation efficiency of light on the radiating surface due to the recesses, it is preferable that the dimension of the opening of the recess in the direction intersecting with the depth direction is not more than one time the wavelength of light emitted from the emitting layer in the layer on which the recesses are formed and also the depth of the recess is not less than one time the wavelength.

Where the translucent conductive layer is provided in a flat surface form having a through hole and the surface of the semiconductor layers exposed at the through hole is also provided as a radiating surface for radiating light emitted from the emitting layer to the outside of the semiconductor layers, a decreased transmittance of light by the translucent conductive layer can be prevented, thereby making it possible to further improve the radiation efficiency of light emitted from the emitting layer and radiated to the outside from the radiating surface.

In order to manufacture the light-emitting element of the present invention, a method for manufacturing the light-emitting element of the present invention comprises; a step of forming semiconductor layers by being subjected to epitaxial growth on a substrate; a step of forming a first conductive layer on the outermost surface of the semiconductor layers; and a step of exposing a back surface of the semiconductor layers by removal of the substrate in a state that the semiconductor layers and the first conductive layer are covered with a protective layer.

According to the manufacturing method of the present invention, the first conductive layer and the semiconductor layers thereunder are covered with a protective layer in the step of removing the substrate, thereby making it possible to prevent contamination or corrosion of these layers by an etching solution and the like for removing the substrate, for example. Further, since the first conductive layer and the semiconductor layers can be mechanically reinforced by the protective layer, these layers can be prevented from being distorted by stress. Therefore, the manufacturing method of the present invention makes it possible to prevent a reduction in yield due to various defects such as the previously-described contamination, corrosion and distortion, thereby manufacturing the light-emitting element of the present invention more efficiently and at a higher productivity.

It is preferable that the substrate is in conformity with semiconductor layers of gallium nitride compounds in a lattice constant and formed by a boride monocrystal capable of forming the semiconductor layers of gallium nitride compounds excellent in crystalline quality and light-emitting efficiency on the surface by being subjected to epitaxial growth. Preferable are monocrystals of zirconium boride or titanium boride as the boride monocrystal.

In the lighting equipment of the present invention, the light-emitting element of the present invention is constituted in combination with at least either a fluorescent material or a phosphorescent material, and therefore excellent in the energy efficiency ratio.

### BRIEF DESCRIPTION OF THE DRAWINGS

FIG. 1 is a sectional view showing one example of the layer constitution of the light-emitting element in the present invention.

FIG. 2 is an enlarged sectional view showing a state that an anti-reflection layer is formed on the back surface of the semiconductor layers which is the radiating surface of the light-emitting element provided as an example in FIG. 1.

FIG. 3 is an enlarged sectional view showing a state that many projections or recesses are formed on the back surface of the semiconductor layers which is the radiating surface of the light-emitting element provided as an example in FIG. 1.

FIG. 4 is a further enlarged sectional view of the projections.

FIG. 5 is a further enlarged sectional view of the recesses.

FIG. 6 is an enlarged sectional view showing a state that an anti-reflection layer is formed on the back surface of the semiconductor layers which is the radiating surface of the light-emitting element shown in FIG. 1 and many projections or recesses are formed on the outer surface of the anti-reflection layer.

FIG. 7 is an enlarged sectional view showing a state that many projections or recesses are formed on the back surface of the semiconductor layers which is a radiating surface of the light-emitting element shown in FIG. 1 and an anti-reflection layer is formed.

FIGS. 8 through 13 are sectional views respectively showing steps of manufacturing the light-emitting element shown in FIG. 1 according to the manufacturing method of the present invention.

FIG. 14 is a sectional view showing another example of the layer constitution of the light-emitting element in the present invention.

FIGS. 15 through 20 are sectional views respectively showing steps of manufacturing the light-emitting element shown in FIG. 14 according to the manufacturing method of the present invention.

FIG. 21 is a sectional view showing another example of the layer constitution of the light-emitting element in the present invention.

FIGS. 22 through 26 are sectional views respectively showing steps of manufacturing the light-emitting element shown in FIG. 21 according to the manufacturing method of the present invention.

FIGS. 27 through 29 are sectional views respectively showing an example of the layer constitution of conventional light-emitting elements.

### DETAILED DESCRIPTION OF THE INVENTION

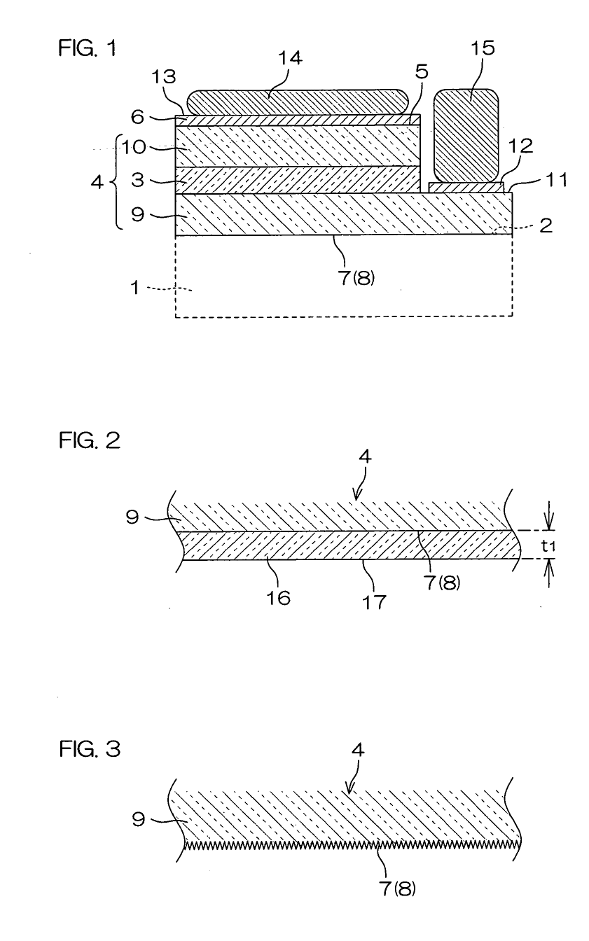

FIG. 1 is a sectional view showing an example of the layer constitution of the light-emitting element in the present invention. With reference to FIG. 1, the light-emitting element provided as an example in the figure is provided with semiconductor layers of gallium nitride compounds (hereinafter also referred to as a “semiconductor layers”) 4 having a multilayer structure including an emitting layer 3 formed by subjecting gallium nitride compounds to epitaxial growth on the surface 2 of a substrate 1 shown in the dotted line in the figure and a conductive reflection layer 6 having electrical conductivity and reflecting light emitted from the emitting layer 3 which is formed, in a state of being electrically connected, on a outermost surface 5 of the semiconductor layers 4 intersecting with the lamination direction, wherein the back surface 7 of the semiconductor layers 4 contacting with the substrate 1 is exposed by removal of the substrate 1 and provided as a radiating surface 8 for radiating light emitted from the emitting layer 3 to the outside of the semiconductor layers 4. The semiconductor layers 4 are constituted by sequentially laminating a first conductive-type semiconductor layer 9, the emitting layer 3 and a second conductive-type semiconductor layer 10 on the surface 2 of the substrate 1.

The surface 11 of the first conductive-type semiconductor layer 9 intersecting with the lamination direction is partially exposed by a partial removal of the emitting layer 3 and the second conductive-type semiconductor layer 10, and a conductive layer 12 is connected to the exposed surface 11. Bump electrodes 14 and 15 for subjecting the light-emitting element provided as an example in the figure for flip chip mounting such as a package are respectively connected on an outer surface 13 opposite a surface contacting with semiconductor layers 4 of a conductive reflection layer 6 and on a conductive layer 12.

In the light-emitting element, a back surface 7 of the semiconductor layers of gallium nitride compounds 4 from which the substrate 1 is removed is provided as a radiating surface 8, and makes it possible to radiate the light to the outside from the radiating surface 8, without passage through the substrate 1, thus solving problems such as absorption and attenuation of light by the substrate 1.

Further, the substrate 1 is not involved in transmission of light, thereby removing the necessity for considering translucency and the like. Therefore, a substrate 1 which is in conformity with semiconductor layers of gallium nitride compounds 4 in a lattice constant and capable of forming the semiconductor layers of gallium nitride compounds 4 excellent in crystalline quality and light-emitting efficiency on the surface by being subjected to epitaxial growth is selectively used as the substrate 1, thus making it possible to improve the light-emitting efficiency of the semiconductor layers 4 thus formed.

In addition, the conductive reflection layer 6 is subsequently provided on the outermost surface 5 of the semiconductor layers 4 formed by epitaxial growth and not restricted in materials, structures and others. Therefore, the conductive reflection layer 6 provided with electrical conductivity and excellent in the reflectance ratio of from blue to ultraviolet light at a wavelength from 350 to 400 nm, in particular, can be selectively used as the conductive reflection layer 6, making it possible to improve the reflectance ratio of light in the conductive reflection layer 6.

Further, in the light-emitting element, a conductive layer 12 is formed at an exposed part of the surface 11 of the first conductive-type semiconductor layer 9 intersecting with the lamination direction, which is opposite the radiating surface 8. The radiating surface 8 is, thus, not obstructed by a conductive layer 12 or a bump electrode 15 used as wiring of the conductive layer 12, thereby making it possible to make a light-emitting area of the light-emitting element as wide as possible in relation to the radiating surface 8.

According to the light-emitting element, light emitted from the emitting layer 3 and radiated to the outside from the radiating surface 8 is greatly improved in radiation efficiency due to connection of the individual effects, thereby making it possible to obtain a higher emission intensity from smaller electrical power.

Further, since the bump electrode 15 is arrayed in the same direction as the bump electrode 14 connected to the outer surface 13 of the conductive reflection layer 6, the light-emitting element can be easily subjected to flip chip mounting on a package or the like, which is another advantage of the present invention.

Of the previously described respective components, a substrate 1 formed of sapphire, silicon carbide (SiC) and others may be used as the substrate 1. However, in the present invention, as explained above, it is preferable that the substrate 1 is selectively used, which is in conformity with semiconductor layers of gallium nitride compounds 4 in a lattice constant and provided with the semiconductor layers 4 excellent in crystalline quality and light-emitting efficiency on the surface 2 by being subjected to epitaxial growth. Examples of the substrate 1 include a substrate formed of boride monocrystal such as zirconium boride (ZrB₂) and titanium boride (TiB₂)

Of semiconductor layers of gallium nitride compounds 4, examples of the emitting layer 3 include various types of emitting layer 3 made of gallium nitride compounds. Favorable examples of the emitting layer 3 include a multiple quantum well structure (MQW) as a super lattice element in which a barrier layer with a thickness of 10 to 100 nm consisting of indium gallium nitride (In_{0.01}Ga_{0.99}N), etc., and a well layer with thickness of 10 to 100 nm consisting of indium gallium nitride (In_{0.11}Ga_{0.89}N) etc., are laminated alternately and in such a way that the bottom layer and the outermost layer can be provided as barrier layers.

Where a first conductive-type semiconductor layer 9 is an n-type semiconductor layer, examples of the first conductive-type semiconductor layer 9 include two-layer structured n-type semiconductor layers laminating a first n-type clad layer with a thickness of 1 to 5 μm consisting of gallium nitride (GaN) etc., and a second n-type clad layer with a thickness of 0.1 to 1 μm consisting of indium gallium nitride (In_{0.02}Ga_{0.98}N) etc., in sequence from the side of the substrate 1.

Where the second conductive-type semiconductor layer 10 is a p-type semiconductor layer, examples of the second conductive-type semiconductor layer 10 include three-layer structured p-type semiconductor layers laminating a first p-type clad layer with a thickness of 50 to 300 nm consisting of aluminum gallium nitride (Al_{0.2}Ga_{0.8}N) etc., a second p-type clad layer with a thickness of 50 to 300 nm consisting of aluminum gallium nitride (Al_{0.2}Ga_{0.8}N) etc., and a p-type contact layer with a thickness of 0.1 to 1 μm consisting of gallium nitride (GaN) etc., in sequence from the side of the emitting layer 3.

However, the first conductive-type semiconductor layer 9 may be a p-type semiconductor layer, while the second conductive-type semiconductor layer 10 may be an n-type semiconductor layer.

It is preferable that the respective layers constituting the semiconductor layers 4 include, for example, a buffer layer with a thickness of 20 to 300 nm consisting of aluminum nitride (AlN), aluminum gallium nitride (AlₓGa₁₋ₓN, wherein x denotes 0≦x<1, or x=0.24 when the substrate 1 is zirconium boride) etc., is formed on the surface 2 of the substrate 1 consisting of boride monocrystal, on which respective layers are formed in sequence by being subjected to epitaxial growth.

Examples of the conductive reflection layer 6 include smooth-surface layers formed of various materials which are able to reflect light emitted from the emitting layer 3 without any loss and provided with electrical conductivity and a favorable ohmic bond with the second conductive-type semiconductor layer 10. Further, the surface of the conductive reflection layer 6 may not be necessarily perfectly smooth, but where the surface is not smooth, care should be taken for a possible decrease in the reflectance ratio.

As explained above, where the second conductive-type semiconductor layer 10 is a p-type semiconductor layer, examples of the conductive reflection layer 6 suitable for combination with the second conductive-type semiconductor layer 10 include thin films consisting of aluminum (Al), titanium (Ti), nickel (Ni), chromium (Cr), indium (In), tin (Sn), molybdenum (Mo), silver (Ag), gold (Au), niobium (Nb), tantalum (Ta), vanadium (V), platinum (Pt), lead (Pb), beryllium (Be), tin oxide (SnO₂), indium oxide (In₂O₃, In₂O), indium tin oxide (ITO), gold/silicon alloy (Au—Si), gold/germanium alloy (Au—Ge), gold/zinc alloy (Au—Zn), gold/beryllium alloy (Au—Be) and others.

The conductive reflection layer 6 may be provided in a single structure or in a laminated structure in which, for example, two or more layers different in ingredient materials are laminated. Preferable as the conductive reflection layer 6 is a thin film formed of aluminum or silver excellent in the reflectance ratio of from blue to ultraviolet light emitted from the emitting layer 3 of the semiconductor layers 4, and even preferable is a thin film formed of aluminum in that it is able to have a favorable ohmic bond with a p-type semiconductor layer in particular.

Examples of the conductive layer 12 include layers formed of various materials having electrical conductivity which are able to attain a favorable ohmic bond with the first conductive-type semiconductor layer 9.

As explained above, when the first conductive-type semiconductor layer 9 is an n-type semiconductor layer, examples of the conductive layer 12 suitable for combination with the first conductive-type semiconductor layer 9 include a thin film consisting of aluminum (Al), titanium (Ti), nickel (Ni), chromium (Cr), indium (In), tin (Sn), molybdenum (Mo), silver (Ag), gold (Au), niobium (Nb), tantalum (Ta), vanadium (V), platinum (Pt), lead (Pb), tungsten (W), tin oxide (SnO₂), indium oxide (In₂O₃, In₂O), indium tin oxide (ITO), gold/silicon alloy (Au—Si), gold/tin alloy (Au—Sn), gold/germanium alloy (Au—Ge), indium/aluminum alloy (In—Al) and others.

In particular, as the conductive layer 12, preferable is a laminated electrode which is a laminate of a titanium layer contacting with the first conductive-type semiconductor layer 9 and an aluminum layer laminated thereon. The laminated electrode attains a favorable ohmic bond with the first conductive-type semiconductor layer 9 and can be bonded to the first conductive-type semiconductor layer 9 at a high bond strength.

Examples of bump electrodes 14 and 15 include bump electrodes 14 and 15 consisting of gold (Au), indium (In), gold/tin alloy solder (Au—Sn), tin/silver alloy solder (Sn—Ag), tin/silver/copper alloy solder (Sn—Ag—Cu), tin/bismuth alloy solder (Sn—Bi), tin/lead alloy solder (Sn—Pb) and others.

In the light-emitting element, when electricity is allowed to flow between the conductive reflection layer 6 and the conductive layer 12 via the bump electrodes 14 and 15, hole and electron (or electron and hole) injected into the semiconductor layers 4 from both of the layers are transported respectively to the second conductive-type semiconductor layer 10 and the first conductive-type semiconductor layer 9 in the thickness direction and recombined in the emitting layer 3, by which gallium nitride compounds constituting the emitting layer 3 are excited to emit light.

Then, light heading from the emitting layer 3 for the first conductive-type semiconductor layer 9 passes through the first conductive-type semiconductor layer 9 and is directly radiated from the radiating surface 8, which is the back surface 7 of the semiconductor layers 4, to the outside of the light-emitting element. Further, light heading from the emitting layer 3 for the outermost surface 5 of the semiconductor layers 4 passes through the second conductive-type semiconductor layer 10, reflected on the outermost surface 5, which is a boundary face between the second conductive-type semiconductor layer 10 and the conductive reflection layer 6 and is radiated from the radiating surface 8 outside of the light-emitting element after passage through the second conductive-type semiconductor layer 10, the emitting layer 3 and the first conductive-type semiconductor layer 9.

As explained above, the back surface 7 of the semiconductor layers 4 exposed by removal of the substrate 1 is provided as a radiating surface 8 of the light-emitting element. The radiating surface 8 may be a surface from which the substrate 1 is only removed. It is, however, preferable to clean the radiating surface 8 by further performing etching treatment after removal of the substrate 1. In addition, the radiating surface 8 may be provided with anti-reflection treatment to reduce the reflectance ratio of light on the radiating surface 8 and improve the transmittance.

FIG. 2 is an enlarged sectional view showing a state that the anti-reflection layer 16 is formed on the radiating surface 8 of the light-emitting element provided as an example in FIG. 1, as anti-reflection treatment.

Examples of the anti-reflection layer 16 include various anti-reflection layers 16 functioning to decrease the reflectance ratio of light emitted from the emitting layer 3 on the radiating surface 8 which is a boundary face between the semiconductor layers of gallium nitride compounds 4 and air and to improve the transmittance. Favorable examples of the anti-reflection layer 16 include layers consisting of inorganic materials such as quartz (SiO₂) and alumina (Al₂O₃) and organic materials such as polycarbonate.

Provision of the radiating surface 8 with the anti-reflection layer 16 can decrease the reflectance ratio of light on the radiating surface 8, improve the transmittance and prevent the light from being repeatedly reflected in the semiconductor layers 4. Therefore, light emitted from the emitting layer 3 and radiated to the outside from the radiating surface 8 can be further improved in radiation efficiency.

It is preferable that the refractive index of the anti-reflection layer 16 is simply decreased from the surface contacting with the semiconductor layers 4 to the outer surface 17 which is opposite the foregoing surface. Such a constitution makes it possible that refractive indexes of the first conductive-type semiconductor layer 9, of semiconductor layers 4, and the anti-reflection layer 16 are made closer on a boundary face between the radiating surface 8, thereby improving the transmittance of light on the boundary face. The refractive indexes of the anti-reflection layer 16 and air are also made closer on a boundary face between the outer surface 17, thereby improving the transmittance of light on the boundary face. Therefore, the transmittance of light on the radiating surface 8 can be further improved. As described above, in order to simply decrease the refractive index of the anti-reflection layer 16, for example, the anti-reflection layer 16 may be formed of a laminate consisting of a plurality of layers different in refractive index.

It is also preferable that the thickness t₁ of the anti-reflection layer 16 is one-quarter of the wavelength of light emitted from the emitting layer 3 in the anti-reflection layer 16. Such a constitution makes it possible that light that has undergone multi-path reflection in the anti-reflection layer 16 mutually weakens the intensity to provide an easy interference, by which a standing wave can be prevented from being occurred in the anti-reflection layer 16 to further increase the transmittance of light in the radiating surface 8.

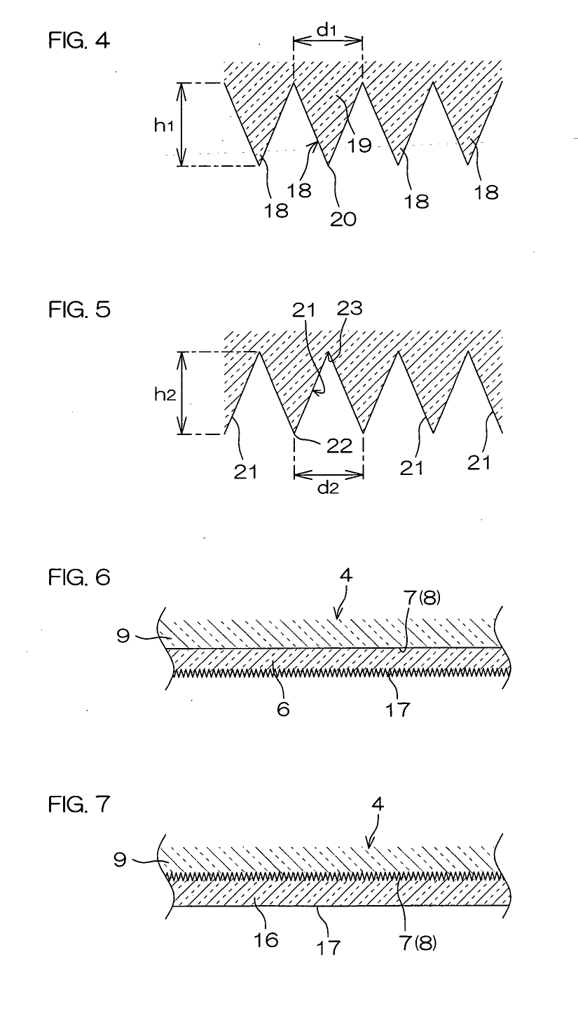

FIG. 3 is an enlarged sectional view showing a state that anti-reflection treatment is provided to form many projections or recesses on the radiating surface 8, which is the back surface 7 of the first conductive-type semiconductor layer 9, of the semiconductor layers 4 of the light-emitting element provided as an example in FIG. 1, thereby making the radiating surface 8 uneven. FIG. 4 is also an enlarged sectional view showing an example of the projections 18 formed on the radiating surface 8 for making the radiating surface 8 uneven.

With reference to the above two figures, the exemplified projections 18 are formed in a conical shape in which an outer diameter, namely, the dimension of the projection 18 in the direction intersecting with the height direction is simply decreased from the base 19 of the projections 18 to the apex 20. When the projections 18 are formded, the radiating surface 8 is formed of an aggregate of conical surfaces having many projections 18 which are inclined to a flat surface intersecting with the lamination direction of the semiconductor layers 4. Therefore, of light emitted from the emitting layer 3 and entering into the radiating surface 8, percentages of components totally reflected due to an incidence angle which exceeds a critical angle established by a boundary face between the semiconductor layers 4 and air can be reduced as compared with a case where the radiating surface 8 is a flat surface, thereby making it possible to reduce the reflectance ratio of light on the surface and improve the transmittance.

Further, in the radiating surface 8 on which many conical projections 18 are provided, an apparent refractive index of the first conductive-type semiconductor layer 9 is simply decreased from the base 19 of the cone to the apex 20, thereby making it possible to decrease the reflectance ratio of light on the radiating surface 8 in terms of the refractive index and improve the transmittance. Therefore, light emitted from the emitting layer 3 and radiated to the outside from the radiating surface 8 can be further improved in radiation efficiency.

The projections 18 may also be formed of pyramid shape in which the base 19 corresponding to the bottom face is any given polygon. The projections 18 in a conical shape or in a pyramid shape may be formed in a curved shape in which a generatrix constituting the surface is free of flexion points. The projections 18 may also be formed, for example, in a hemispheric shape. The projections 18 having such shapes are able to provide similar effects to those in the conical shape.

It is preferable in improving the above effects by the projections 18 that the dimension of the base 19 of the projection 18 in the direction intersecting with the height direction (outer diameter d₁ in a conical shape) is not more than one time the wavelength of light emitted from the emitting layer 3 in the first conductive-type semiconductor layer 9 which forms the projections 18, and the height h₁ of the projections 18 is not less than one time the wavelength.

FIG. 5 is also an enlarged sectional view showing one example of recesses 21 formed on the radiating surface 8 for making the radiating surface 8 uneven. With reference to FIGS. 3 and 5, the exemplified recesses 21 are formed of a conical surface in which the inner diameter, namely, a dimension of the recesses 21 in the direction intersecting with the depth direction is simply decreased from the opening 22 of the recesses 21 to the deepest point 23. When the recesses 21 are formed, the radiating surface 8 is formed of an aggregate of conical surfaces which are surfaces of the recesses 21 and inclined to a flat surface intersecting with the lamination direction of the semiconductor layers 4. Therefore, of light emitted from the emitting layer 3 and entering into the radiating surface 8, percentages of components totally reflected due to an incidence angle which exceeds a critical angle established by a boundary face between the semiconductor layers 4 and air can be reduced as compared with a case where the radiating surface 8 is a flat surface, thereby making it possible to reduce the reflectance ratio of light on the surface and improve the transmittance.

Further, in the radiating surface 8 on which many recesses 21 formed of a conical surface are provided, an apparent refractive index of the first conductive-type semiconductor layer 9 is simply decreased from the deepest point 23 to the opening 22, which is a base of the cone, thereby making it possible to decrease the reflectance ratio of light on the radiating surface 8 in terms of the refractive index and improve the transmittance. Therefore, light emitted from the emitting layer 3 and radiated outside from the radiating surface 8 can be further improved in radiation efficiency.

The recesses 21 may also be formed of pyramid surfaces in which the opening 22 corresponding to the bottom face is any given polygon. The recesses 21 constituted with conical surfaces or pyramid surfaces may be formed in a curved shape in which a generatrix constituting the surface is free of flexion points. The recesses 21 may also be formed, for example, in a hemispheric surface. The recesses 21 having such surfaces are able to provide similar effects to those in the conical surface.

It is preferable in improving the above effects by the recesses 21 that the dimension of the opening 22 of the recesses 21 in the direction intersecting with the depth direction (inner diameter d₂ in a conical shape) is not more than one time the wavelength of light emitted from the emitting layer 3 in the first conductive-type semiconductor layer 9 which forms the recesses 21, and the depth h₂ of the recesses 21 is not less than one time the wavelength.

FIGS. 6 and 7 are sectional views in which a modified example of the radiating surface 8 is enlarged.

With reference to FIG. 6, in this example, of the semiconductor layers 4 of the light-emitting element provided as an example in FIG. 1, an anti-reflection layer 6 is formed on the radiating surface 8, which is the back surface 7 of the first conductive-type semiconductor layer 9, and projections or recesses are formed on the outer surface 17 of the anti-reflection layer 6 to make the outer surface 17 uneven. Examples of the anti-reflection layer 6 include an anti-reflection layer 6 which is constituted similarly to that described above in FIG. 2. The configuration and dimension of the projections or recesses formed on the outer surface 17 of the anti-reflection layer 6 are similar to those shown in FIGS. 3 through 5. Further, outer diameter d₁ and height h₁ of the base 19 of the projection 18 and inner diameter d₂ and depth h₂ of the opening 22 of the recesses 21 are specified on the basis of the wavelength of light emitted from the emitting layer 3 in the anti-reflection layer 6.

With reference to FIG. 7, in this example, of the semiconductor layers 4 of the light-emitting element provided as an example in FIG. 1, projections or recesses are formed on the radiating surface 8 which is the back surface of the first conductive-type semiconductor layer 9 to make the radiating surface 8 uneven, on which the anti-reflection layer 6 is formed. The configuration and dimension of the projections or recesses formed on the radiating surface 8 are similar to those shown in FIGS. 3 through 5. Further, examples of the anti-reflection layer 6 includes an anti-reflection layer 6 which is structured similarly to that previously described in FIG. 2.

Such a constitution makes it possible to further improve the radiation efficiency of light emitted from the emitting layer 3 and radiated to the outside from the radiating surface 8 due to compound effect of the anti-reflection layer 6 with uneven surfaces.

In order to provide the projections 18 or recesses 21 with the radiating surface 8 or the outer surface 17, either of these surfaces may be subjected to a selective etching in combination of photolithographic technology with dry or wet etching. It is preferable in improving the radiation efficiency of light that the projections 18 or recesses 21 are provided as closely as possible and in as large numbers as possible on the radiating surface 8 or the outer surface 17.

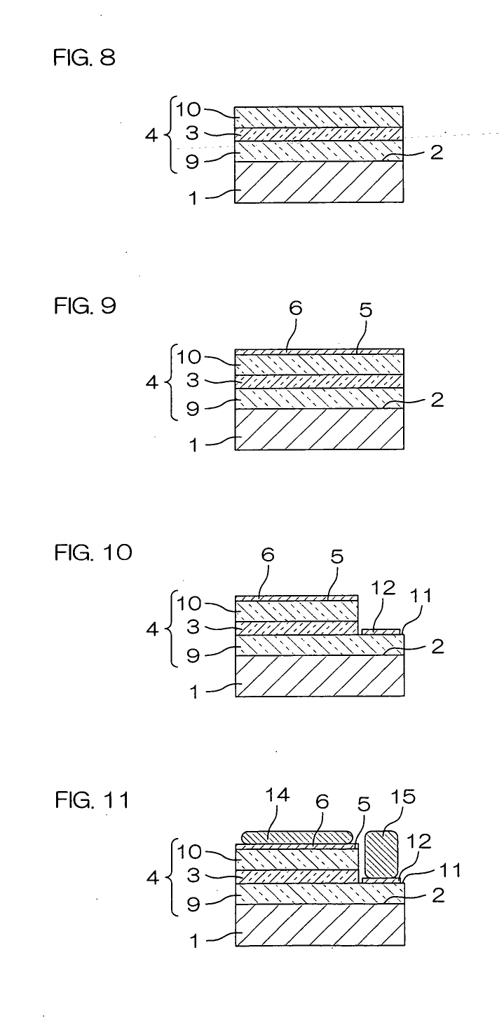

FIGS. 8 through 13 are sectional views respectively showing steps of manufacturing the light-emitting element shown in FIG. 1 according to the manufacturing method of the present invention.

With reference to FIG. 8, in the manufacturing method of the present invention, first, gallium nitride compounds are subjected to epitaxial growth on the surface 2 of the substrate 1 to form semiconductor layers of gallium nitride compounds 4 having a multilayer structure. Metal organic chemical vapor deposition (MOCVD) is particularly preferable as a method for subjecting the semiconductor layers 4 to epitaxial growth on the substrate 1. The MOCVD is capable of continuously subjecting the respective layers constituting the semiconductor layers 4 to epitaxial growth on the surface 2 of the substrate 1.

To be specific, a substrate 1 is set in the chamber of the equipment for performing the MOCVD and, while the substrate 1 is kept at a temperature suitable for the growth of each layer, material gases resulting in formation of each layer are introduced to cause chemical reaction on the surface 2 of the substrate 1, thereby allowing gallium nitride compounds having a predetermined composition to deposit on the surface 2 of the substrate 1. This operation is repeated for each layer to form the semiconductor layers 4 having a predetermined lamination structure.

Where a substrate 1 formed of boride monocrystal such as zirconium boride (ZrB₂) or titanium boride (TiB₂) is used, for example, as the substrate 1 and the semiconductor layers 4 consisting of layers of gallium nitride compounds (plural layers including a buffer layer explained above) is formed on the surface 2 of the substrate 1, a buffer layer consisting of aluminum nitride (AlN) or aluminum gallium nitride (AlₓGa₁₋ₓN, wherein x denotes 0≦x<1, or x=0.24 when the substrate 1 is zirconium boride) is formed on the surface 2 of the substrate 1 in a state that the substrate 1 set in the chamber is kept at temperatures from 400 to 950° C.

Next, in a state that the substrate 1 is kept at temperatures from 950 to 1150° C., a first n-type clad layer consisting of gallium nitride (GaN) is formed on the buffer layer, and thereafter in a state that the substrate 1 is kept at temperatures of about 700° C., a second n-type clad layer consisting of indium gallium nitride (In_{0.02}Ga_{0.98}N) is laminated to form the first conductive-type semiconductor layer 9, which is a two layer structured n-type semiconductor layer.

Next, in a state that the substrate 1 is kept at temperatures of about 700° C., a barrier layer consisting of indium gallium nitride (In_{0.01}Ga_{0.99}N) and a well layer consisting of indium gallium nitride (In_{0.11}Ga_{0.89}N) are alternately laminated on the first conductive-type semiconductor layer 9 in such a way that the bottom layer and the uppermost layer can be provided as a barrier layer, thereby forming a multiple quantum well structure (MQW) as a super lattice element, which is provided as an emitting layer 3.

Then, in a state that the substrate 1 is kept at temperatures of about 700° C., a first p-type clad layer consisting of aluminum gallium nitride (Al_{0.2}Ga_{0.8}N) is formed on the emitting layer 3, thereafter, in a state that the substrate 1 is kept at temperatures of about 820° C., a second p-type clad layer consisting of aluminum gallium nitride (Al_{0.2}Ga_{0.8}N) is laminated, and then, in a state that the substrate 1 is kept at temperatures of about 820 to 1050° C., ap-type contact layer consisting of gallium nitride (GaN) is laminated to form a second conductive-type semiconductor layer 10, which is a three-layer structured p-type semiconductor layer, resulting in formation of the semiconductor layers 4.

With reference to FIG. 9, in the manufacturing method of the present invention, the conductive reflection layer 6 is formed on the outermost surface 5 of the semiconductor layers 4 formed on the surface of the substrate 1 intersecting with the lamination direction by vacuum deposition method or sputtering method.

Next, with reference to FIGS. 10 and 11, of the semiconductor layers 4, the emitting layer 3 and the second conductive-type semiconductor layer 10 are partially removed by dry or wet etching, together with the conductive reflection layer 6 formed on the second conductive-type semiconductor layer 10, to expose a part of the surface 11 intersecting with the lamination direction of the first conductive-type semiconductor layer 9, the conductive layer 12 is formed on the surface 11 thus exposed by the vacuum deposition method or sputtering method, and thereafter, bump electrodes 14 and 15 are connected respectively to the conductive layer 12 thus formed and the outer surface 7 of the conductive reflection layer 6. The bump electrodes 14 and 15 are formed, for example, by using screen printing and others to be provided in a predetermined flat surface form with electrically conductive paste containing ingredient metals.

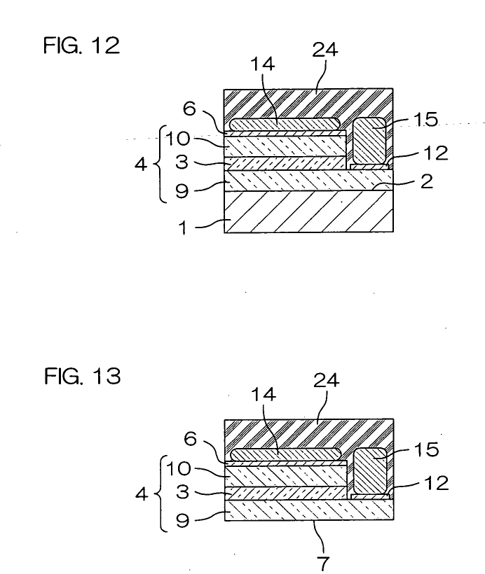

Next, with reference to FIGS. 12 and 13, after the semiconductor layers 4, the conductive reflection layer 6, the conductive layer 12 and the bump electrodes 14 and 15 are covered with a protective layer 24, the substrate 1 is removed to expose the back surface 7 of the semiconductor layers 4.

The protective layer 24 can be formed of inorganic or organic materials which can stand treatments in a step of removing the substrate 1. The protective layer 24 is formed by using coating materials including the above materials in such a way as to cover the various parts by spin coating and others.

The substrate 1 can be removed by using an optimal removing method selected from chemical or mechanical removing methods, depending on materials of the substrate 1. For example, where the substrate 1 is formed of monocrystal of zirconium boride, acids and others may be used as an etchant to subject the substrate 1 to chemical etching. Further, where the substrate 1 is formed of sapphire, a laser beam with a wavelength of about 370 nm may be radiated to the boundary face between the substrate 1 and the semiconductor layers 4, thereby melting a part of the semiconductor layers 4 to detach the substrate 1.

Thereafter, the exposed back surface 7 of the semiconductor layers 4 is subjected to etching for cleaning whenever necessary, and the protective layer 24 is removed, for example, by dry etching, resulting in manufacture of the light-emitting element shown in FIG. 1 where the back surface 7 is provided as a radiating surface 8.

According to the manufacturing method of the present invention, the semiconductor layers 4, the conductive reflection layer 6, the conductive layer 12 and the bump electrodes 14 and 15 are covered with the protective layer 24 in the step of removing the substrate 1, thereby making it possible to prevent contamination or corrosion of these layers, for example, by an etching solution and the like for removing the substrate 1. Further, since these respective layers can be mechanically reinforced by the protective layer 24, these layers can be prevented from being distorted by stress. Therefore, the manufacturing method of the present invention makes it possible to prevent a reduction in yield due to various defects such as the previously described contamination, corrosion and distortion, thereby manufacturing the light-emitting element more efficiently and at higher productivity.

Where the previously described anti-reflection layer 16 is formed on the radiating surface 8 and the projections 18 or recesses 21 are formed on the radiating surface 8 or on the outer surface 17 of the anti-reflection layer 16 to make the surfaces uneven, the above treatment can be performed at any time before or after the protective layer 24 is removed. However, it is preferable to perform the treatment before removal of the protective layer 24, with consideration given to protection of the layers constituting the light-emitting element.

In the lighting equipment of the present invention, the light-emitting element of the present invention is constituted in combination with at least either a fluorescent material or a phosphorescent material. As the fluorescent material or the phosphorescent material, various fluorescent materials and/or phosphorescent materials which emit any given light in response to illumination of from blue to ultraviolet light with a wavelength from 350 to 400 nm radiated from the radiating surface of a light-emitting element may be used solely or in combination with two or more types of them.

In the lighting equipment of the present invention, since the light-emitting element of the present invention is used as a light source, it is excellent in the energy efficiency ratio and able to attain an energy efficiency ratio which is not less than two times as great as that of a fluorescent lamp in particular.

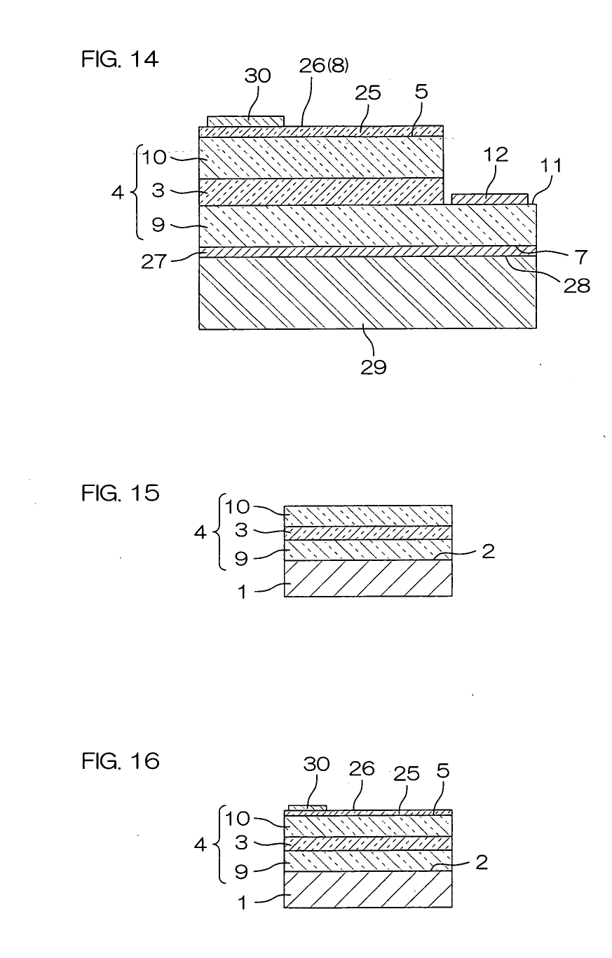

FIG. 14 is a sectional view showing another example of the layer constitution of the light-emitting element in the present invention. With reference to FIG. 14, an example of the light-emitting element given in the figure is provided with semiconductor layers of gallium nitride compounds 4 having a multilayer structure including an emitting layer 3 formed by subjecting gallium nitride compounds to epitaxial growth on the surface of the substrate (not illustrated) and a translucent conductive layer 25 having electrical conductivity and transmitting light emitted from the emitting layer 3 which is formed on the outermost surface 5 of the semiconductor layers 4 intersecting with the lamination direction in a state of being electrically connected, wherein the outer surface 26 of the translucent conductive layer 25, which is opposite a surface contacting with the semiconductor layers 4 is provided as a radiating surface 8 for radiating light emitted from the emitting layer 3 to the outside of the semiconductor layers 4. The semiconductor layers 4 are constituted by sequentially laminating the first conductive-type semiconductor layer 9, the emitting layer 3 and the second conductive-type semiconductor layer 10 on the surface of the substrate.

The back surface 7 of the semiconductor layers 4 which contacts with the substrate is exposed after removal of the substrate, a reflection layer 27 for reflecting light emitted from the emitting layer 3 is then formed on the exposed back surface 7, and a support 29 is joined on the outer surface 28 of the reflection layer 27 which is opposite a surface contacting with the semiconductor layers 4.

A part of the surface 11 of the first conductive-type semiconductor layer 9 intersecting with the lamination direction is exposed by a partial removal of the emitting layer 3 and the second conductive-type semiconductor layer 10, and a conductive layer 12 is connected to the thus exposed surface 11. An electrode pad 30 is connected to the outer surface 26 of the translucent conductive layer 25.

In the light-emitting element, a reflection layer 27 for reflecting light emitted from the emitting layer 3 is formed on the back surface 7 of the semiconductor layers of gallium nitride compounds 4 from which the substrate is removed, and the light can be radiated to the outside from the radiating surface 8, which is the outer surface 26 of the translucent conductive layer 25 formed on the outermost surface 5 of the semiconductor layers 4, without passage through the substrate, thereby making it possible to solve the problems such as absorption and attenuation of light by the substrate.

Further, the substrate is not involved in transmission of light, thereby removing the necessity for considering translucency and the like. Therefore, a substrate which is in conformity with semiconductor layers of gallium nitride compounds 4 in a lattice constant and capable of forming the semiconductor layers 4 excellent in crystalline quality and light-emitting efficiency on the surface by being subjected to epitaxial growth is selectively used as the substrate, thus making it possible to improve the light-emitting efficiency of the semiconductor layers 4 thus formed.

In addition, the reflection layer 27 is subsequently provided on the back surface 7 of the semiconductor layers 4 formed by epitaxial growth and not restricted in materials, structures and others. Therefore, a reflection layer 27 excellent in the reflectance ratio of from blue to ultraviolet light at a wavelength from 350 to 400 nm, in particular, can be selectively used as the reflection layer 27, making it possible to improve the reflectance ratio of light in the reflection layer 27.

The translucent conductive layer 25 is also subsequently provided on the outermost surface 5 of the semiconductor layers 4 formed by epitaxial growth and not restricted in materials, structures and others. Therefore, a translucent conductive layer 25 excellent in transmittance of from blue to ultraviolet light can be selectively used as the translucent conductive layer 25, making it possible to improve the transmittance of light in the translucent conductive layer 25.

Therefore, according to the light-emitting element, light emitted from the emitting layer 3 and radiated to the outside from the radiating surface 8 is greatly improved in radiation efficiency due to connection of the individual effects, thereby making it possible to obtain a higher emission intensity from smaller electrical power.

When the support 29 is joined on the outer surface 28 of the reflection layer 27, the semiconductor layers 4 can be reinforced by the support 29, thereby making it possible to improve the strength of a light-emitting element and facilitate the handling of the element. For example, the support 29 is used as abase for the light-emitting element, by which the light-emitting element can be reliably mounted into packages and the like. Further, the support 29 is subsequently joined after formation of the reflection layer 27 by removal of the substrate and not restricted in materials, structures and others. Thus, a support 29 which is close to the semiconductor layers 4 in the coefficient of thermal expansion and excellent in desired characteristics such as heat conduction characteristics, electrical conduction characteristics and mechanical characteristics can be used selectively as the support 29 to improve the reliability of the light-emitting element.

Of the respective components, the substrate, the semiconductor layers 4 and the conductive layer 12 can be constituted similarly of similar materials to those shown in FIG. 1.

The translucent conductive layer 25 includes layers formed of various materials which are able to transmit light emitted from the emitting layer 3 without any loss, and which are provided with electrical conductivity and a favorable ohmic bond with the second conductive-type semiconductor layer 10 of the semiconductor layer 4.

Where the second conductive-type semiconductor layer 10 is a p-type semiconductor layer, examples of the translucent conductive layer 25 suitable for combination with the second conductive-type semiconductor layer 10 include thin films consisting of aluminum (Al), titanium (Ti), nickel (Ni), chromium (Cr), indium (In), tin (Sn), molybdenum (Mo), silver (Ag), gold (Au), niobium (Nb), tantalum (Ta), vanadium (V), platinum (Pt), lead (Pb), beryllium (Be), gold/silicon alloy (Au—Si), gold/germanium alloy (Au—Ge), gold/zinc alloy (Au—Zn), gold/beryllium alloy (Au—Be), etc., and designed to be made thin so as to be provided with translucence and transparent conductive films such as tin oxide (SnO₂), indium oxide (In₂O₃, In₂O), indium tin oxide (ITO). A two- or more layered laminate made with the films may be used as the translucent conductive layer 25.

A semi-transparent electrode, which is a laminate consisting of a nickel thin film contacting with the second conductive-type semiconductor layer 10 and a gold thin film laminated thereon, is particularly preferable as the translucent conductive layer 25. The semi-transparent electrode is able to attain a favorable ohmic bond with the second conductive-type semiconductor layer 10 and also allow electricity to flow uniformly through the semiconductor layers 4.

The translucent conductive layer 25 is provided in a flat surface form having a through hole, and the outermost surface 5 of the semiconductor layers 4 exposed at the through hole is also allowed to function as a radiating surface 8. In this instance, a decreased transmittance of light by the translucent conductive layer 25 can be prevented, thereby making it possible to further improve the radiation efficiency of light emitted from the emitting layer 3 and radiated to the outside from the radiating surface 8.

Examples of the reflection layer 27 include smooth-surface layers formed of various materials which are able to reflect light emitted from the emitting layer 3 without any loss. Further, the surface of the reflection layer 27 may not be necessarily perfectly smooth, but where the surface is not smooth, care should be taken a possible decrease in the reflectance ratio. The reflection layer 27 may be made with a layer other than a metal layer as long as it can reflect light. In general, if it is made with a metal layer excellent in heat conductivity, heat generated on light emission can be favorably released through the reflection layer 5.

Examples of the reflection layer 27 include thin films consisting of aluminum (Al), titanium (Ti), nickel (Ni), chromium (Cr), indium (In), tin (Sn), molybdenum (Mo), silver (Ag), gold (Au), niobium (Nb), tantalum (Ta), vanadium (V), platinum (Pt), lead (Pb), beryllium (Be), tin oxide (SnO₂), indium oxide (In₂O₃, In₂O), indium tin oxide (ITO), gold/silicon alloy (Au—Si), gold/germanium alloy (Au—Ge), gold/zinc alloy (Au—Zn), gold/beryllium alloy (Au—Be) and others. Preferable is a thin film formed of titanium, aluminum or silver excellent in heat radiation and reflectance ratio of from blue to ultraviolet light emitted from the emitting layer 3 of the semiconductor layers 4, as the reflection layer 27.

As explained above, a support 29 which is close to the semiconductor layers 4 in the coefficient of thermal expansion or excellent in desired characteristics such as heat conduction characteristics, electrical conduction characteristics and mechanical characteristics can be used selectively as the support 29. A support 29 consisting of aluminum nitride (AlN), silicon carbide (SiC), copper (Cu), copper/tungsten alloy (Cu—W) and silicon (Si) may be used as the support 29. Particularly preferable is the support 29 which is formed of silicon excellent in the respective characteristics.

Silicon is also excellent in workability which is one of mechanical characteristics and advantageous in improving the productivity of a light-emitting element when used in the support 29. In other words, in a practical manufacture of light-emitting elements, the respective layers from a first conductive-type semiconductor layer 9 to a translucent conductive layer 25 similar in size to the substrate are formed on an entire surface of the substrate (wafer) large enough to include a plurality of light-emitting elements. Next, an electrode pad 30 is provided at a predetermined site inside an area of each light-emitting element of the outer surface 26 of the translucent conductive layer 25, and the emitting layer 3 and the second conductive-type semiconductor layer 10 at a predetermined site inside an area of each light-emitting element are partially removed to expose a part of the surface 11 of the first conductive-type semiconductor layer 9, thereby providing an electrode pad 12 on the exposed surface

Then, a reflection layer 27 similar in size to the substrate is formed on an entire surface of the back surface 7 exposed after removal of the substrate, and after a support 29 similar in size to the substrate is joined on an entire surface of the outer surface 28 of the reflection layer 27, each area is cut out to manufacture a plurality of light-emitting elements. Therefore, use of a support 29 consisting of silicon excellent in workability as the support 29 makes it possible to improve the workability, when the area is cut out, easily cut out individual light-emitting elements and improve the productivity of light-emitting elements.

Examples of an electrode pad 30 include a thin film of titanium (Ti), or a laminate of a thin film of titanium (Ti) contacting with the translucent conductive layer 26 and a thin film of gold (Au) laminated thereon. The electrode pad 30 can also be connected to the conductive layer 12.

In the light-emitting element, when electricity is allowed to flow between the translucent conductive layer 25 and the conductive layer 12, hole and electron (or electron and hole) injected into the semiconductor layers 4 from both sides are transported respectively to the second conductive-type semiconductor layer 10 and the first conductive-type semiconductor layer 9 in the thickness direction and recombined in the emitting layer 3, by which gallium nitride compounds constituting the emitting layer 3 are excited to emit light.

Then, light heading from the emitting layer 3 for the outermost surface 5 of the semiconductor layers 4 passes through the second conductive-type semiconductor layer 10 and the translucent conductive layer 25, and is directly radiated from the radiating surface 8, which is the outer surface 26 of the translucent conductive layer 25, to the outside of the light-emitting element. Further, light heading from the emitting layer 3 for the first conductive-type semiconductor layer 9 passes through the first conductive-type semiconductor layer 9, reflected on the back surface 7 of the semiconductor layers 4, which is a boundary face between the first conductive-type semiconductor layer 9 and the reflection layer 27, and passes through the first conductive-type semiconductor layer 9, the emitting layer 3, the second conductive-type semiconductor layer 10 and the translucent conductive layer 25, and is radiated from the radiating surface 8 to the outside of the light-emitting element.

In the light-emitting element provided as an example in FIG. 14, an anti-reflection layer may be provided between the outermost surface 5 of the semiconductor layers 4 and the translucent conductive layer 25 or the outer surface 26 of the translucent conductive layer 25. In this instance, the reflectance ratio of light on any of the surfaces is decreased to improve the transmittance, thereby making it possible to prevent the light from being repeatedly reflected in the semiconductor layers 4. Therefore, the radiation efficiency of light emitted from the emitting layer 3 and radiated outside from the radiating surface 8 can be further improved.

The anti-reflection layer may be constituted in the same way with similar materials to those shown in FIG. 2. For example, it is preferable that the refractive index of the anti-reflection layer is simply decreased from a surface contacting with the semiconductor layers 4 to a surface contacting with the translucent conductive layer 25 or from a surface contacting with the translucent conductive layer 25 to an outer surface which is opposite the foregoing surface. It is also preferable that the thickness of the anti-reflection layer is formed one-quarter of the wavelength of light emitted from the emitting layer 3 in the anti-reflection layer.

For the same purpose with the anti-reflection layer, it is preferable that many projections are formed on the outermost surface 5 of the semiconductor layers 4 or the outer surface of the anti-reflection layer and the dimension of the projection in the direction intersecting with the height direction is simply decreased from the base of the projection to the apex.

The projections may be constituted similarly to those shown in FIG. 4. For example, the projections may be formed in any given shape such as the conical shape, the pyramid shape, in the conical shape or in the pyramid shape may be formed in a curved shape in which a generatrix constituting the surface is free of flexion points, and a hemispheric shape. Further, it is preferable that the dimension of the base of the projection in the direction intersecting with the height direction is not more than one time the wavelength of light emitted from the emitting layer 3 in the layer on which the projections are formed, and the height of the projection is not less than one time the wavelength.

For the same purpose with the anti-reflection layer, it is preferable that many recesses are formed on the outermost surface 5 of the semiconductor layers 4 or the outer surface of the anti-reflection layer and the dimension of the recess in the direction intersecting with the depth direction is simply decreased from the opening of the recess to the bottom.

The recesses are constituted similarly to those shown in FIG. 5. For example, the recess may be formed in any given surface such as the conical surface, pyramid surface, in the conical surface or in the pyramid surface may be formed in a curved shape in which a generatrix constituting the surface is free of flexion points, and a hemispheric surface. Further, it is preferable that the dimension of the opening of the recess in the direction intersecting with the depth direction is not more than one time the wavelength of light emitted from the emitting layer in the layer on which the recesses are formed, and the depth of the recess is not less than one time the wavelength.

FIGS. 15 through 20 are sectional views respectively showing steps of manufacturing the light-emitting element shown in FIG. 14 according to the manufacturing method of the present invention.

With reference to FIG. 15, in the manufacturing method of the present invention, gallium nitride compounds are first subjected to epitaxial growth on the surface 2 of the substrate 1, thereby forming semiconductor layers of gallium nitride compounds 4 having a multilayer structure. The method for subjecting the semiconductor layers 4 to epitaxial growth on the substrate 1 is the same as that which has been explained above.

Next, with reference to FIG. 16, a translucent conductive layer 25 is provided on the outermost surface 5 of the semiconductor layers 4 formed on the surface 2 of the substrate 1 intersecting with the lamination direction by the vacuum deposition method or sputtering method, and then an electrode pad 30 is formed on the outer surface 26 of the translucent conductive layer 25 thus formed by the vacuum deposition method or sputtering method.

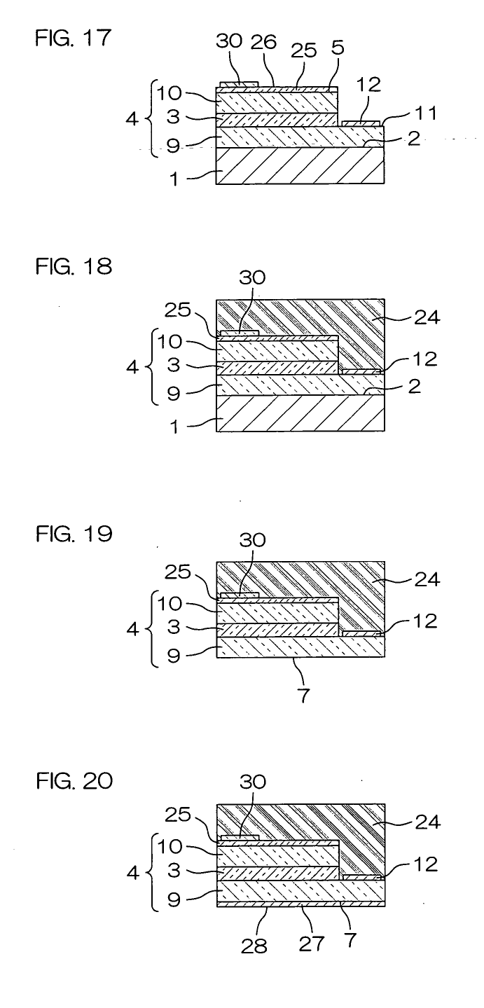

Next, with reference to FIG. 17, of the semiconductor layers 4, the emitting layer 3 and the second conductive-type semiconductor layer 10 are partially removed by dry or wet etching, together with the translucent conductive layer 25 formed on the second conductive-type semiconductor layer 10, to expose a part of the surface 11 intersecting with the lamination direction of the first conductive-type semiconductor layer 9, and thereafter the conductive layer 12 is formed on the exposed surface 11 by the vacuum deposition method or sputtering method.

Next, with reference to FIGS. 18 through 20, the semiconductor layers 4, the conductive layer 12, the translucent conductive layer 25 and the electrode pad 30 are covered with the protective layer 24, the substrate 1 is removed to expose the back surface 7 of the semiconductor layers 4, cleaned by etching, when necessary, and thereafter the reflection layer 27 is formed on the back surface 7 by the vacuum deposition method or sputtering method.

Thereafter, the support 29 is joined on the outer surface 28 of the reflection layer 27, and the protective layer 24 is then removed by dry etching, for example, to manufacture the light-emitting element shown in FIG. 14.

According to the manufacturing method of the present invention, the semiconductor layers 4, the conductive layer 12, the translucent conductive layer 25 and the electrode pad 30 are covered with the protective layer 24 in the step of removing the substrate 1, thereby making it possible to prevent contamination or corrosion of these layers by an etching solution and the like for removing the substrate 1. Further, since these layers can be mechanically reinforced by the protective layer 24, they can also be prevented from being distorted by stress. Therefore, the manufacturing method of the present invention is able to prevent a reduction in yield due to various defects such as the previously-described contamination, corrosion and distortion, thereby manufacturing the light-emitting element more efficiently and at higher productivity.

In the lighting equipment of the present invention, the light-emitting element of the present invention is constituted in combination with at least either of a fluorescent material or a phosphorescent material. Various fluorescent materials and/or phosphorescent materials which emit any given light in response to illumination of from blue to ultraviolet light having a wavelength of 350 to 400 nm radiated from the radiating surface of the light-emitting element may be used solely or in combination of two or more types of them as the fluorescent material and the phosphorescent material.

In the lighting equipment of the present invention, since the light-emitting element of the present invention is used as a light source, it is excellent in the energy efficiency ratio and able to attain an energy efficiency ratio which is not less than two times as great as that of a fluorescent lamp in particular.

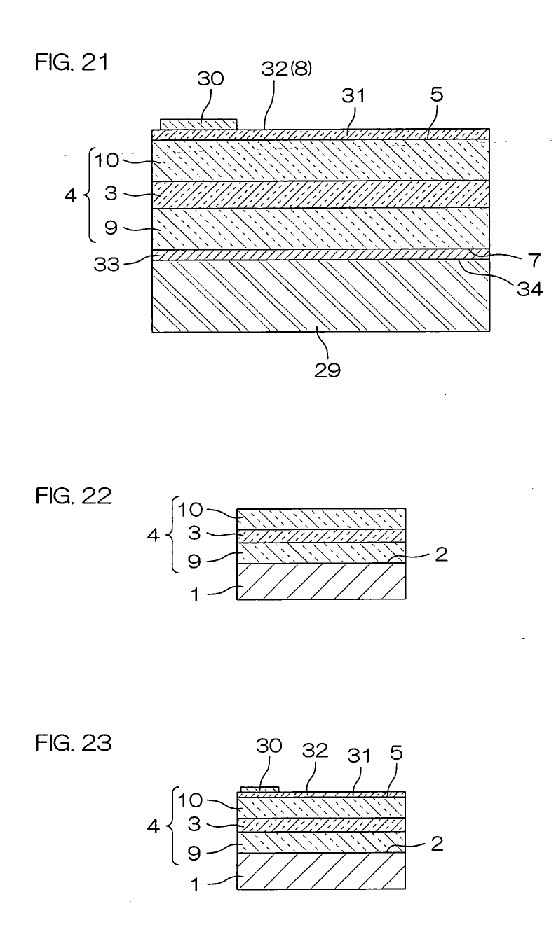

FIG. 21 is a sectional view showing another example of the layer constitution of the light-emitting element in the present invention. With reference to FIG. 21, the light-emitting element shown in the figure is provided with semiconductor layers of gallium nitride compounds 4 having a multilayer structure including an emitting layer 3 formed by subjecting gallium nitride compounds to epitaxial growth on the surface of the substrate (not illustrated) and a first conductive layer 31 as a translucent conductive layer for transmitting light emitted from the emitting layer 3 which is formed on the outermost surface 5 of the semiconductor layers 4 intersecting with the lamination direction in a state of being electrically connected, wherein the outer surface 32 of the first conductive layer 31, which is opposite a surface contacting with the semiconductor layers 4 is provided as a radiating surface 8 for radiating light emitted from the emitting layer 3 to the outside of the semiconductor layers 4. The semiconductor layers 4 are constituted by sequentially laminating the first conductive-type semiconductor layer 9, the emitting layer 3 and the second conductive-type semiconductor layer 10 on the surface of the substrate. An electrode pad 30 is connected to the outer surface 32 of the first conductive layer 31.

The back surface 7 of the semiconductor layers 4 which contacts with the substrate is exposed after removal of the substrate, a conductive reflection layer 33 for reflecting light emitted from the emitting layer 3 is then formed on the exposed back surface 7 in a state of being connected, and a support 29 is joined on the outer surface 34 of the conductive reflection layer 33 which is opposite a surface contacting with the semiconductor layers 4.

In the light-emitting element of the present invention, the second conductive layer 33 as a conductive reflection layer is formed on the back surface 7 of the semiconductor layers of gallium nitride compounds 4 from which the substrate is removed, thus making it possible to radiate light emitted from the emitting layer 3 to the outside from the radiating surface 8 which is the outer surface 32 of the first conductive layer 31 as a translucent conductive layer formed on the outermost surface 5 of the semiconductor layers 4, without passage through the substrate, thereby solving problems such as absorption and attenuation of light by the substrate.

Further, as described previously, the substrate is not involved in transmission of light, thereby removing the necessity for considering translucency and the like. Therefore, the substrate which is in conformity with semiconductor layers of gallium nitride compounds in a lattice constant and capable of forming the semiconductor layers 4 excellent in crystalline quality and light-emitting efficiency on the surface by being subjected to epitaxial growth can be selectively used as the substrate, thereby making it possible to improve the light-emitting efficiency of the thus formed semiconductor layers 4.

In addition, the second conductive layer 33 is subsequently provided on the back surface 7 of the semiconductor layers 4 formed by epitaxial growth and not restricted in materials, structures and others. Therefore, a conductive reflection layer having electrical conductivity and excellent in the reflectance ratio of from blue to ultraviolet light at a wavelength from 350 to 400 nm, in particular, can be selectively used as the second conductive layer 33, making it possible to improve the reflectance ratio of light in the second conductive layer 33.

In addition, the first conductive layer 31 is subsequently provided on the outermost surface 5 of the semiconductor layers 4 formed by epitaxial growth and not restricted in materials, structures and others. Therefore, a translucent conductive layer excellent in transmittance of from blue to ultraviolet light, in particular, can be selectively used as the first conductive layer 31, thus making it possible to improve the transmittance of light in the first conductive layer 31.

Therefore, according to the light-emitting element, light emitted from the emitting layer 3 and radiated to the outside from the radiating surface 8 is greatly improved in radiation efficiency due to connection of the individual effects, thereby making it possible to obtain a higher emission intensity from smaller electrical power.

When the support 29 is joined on the outer surface 34 of the second conductive layer 33, the semiconductor layers 4 can be reinforced by the support 29, thereby making it possible to improve the strength of a light-emitting element and facilitate the handling of the element. For example, the support 29 is used as a base for the light-emitting element, by which the light-emitting element can be reliably mounted into packages and the like. Further, the support 29 is subsequently joined after formation of the second conductive layer 33 by removal of the substrate and not restricted in materials, structures and others. Thus, a support 29 which is close to the semiconductor layers 4 in the coefficient of thermal expansion and excellent in desired characteristics such as heat conduction characteristics, electrical conduction characteristics and mechanical characteristics can be used selectively as the support to improve the reliability of the light-emitting element. Particularly, when those having electrical conductivity are used as the support 29, it is possible to easily wire the second conductive layer 33 and mount the light-emitting element into packages and the like. Further, use of those having insulation properties or semi-conductivity as the support 29 makes it possible to secure insulation properties between the second conductive layer 33 and packages etc.

In the present invention, the first conductive layer 31 may be a conductive reflection layer and the second conductive layer 33 may be a translucent conductive layer. In this instance, a translucent conductive layer having electrical conductivity and excellent in transmittance of from blue to ultraviolet light, in particular, which is not restricted in materials, structures and the like may be selectively used as the second conductive layer 33, thus the transmittance of light in the second conductive layer 33 can be improved. Therefore, it can be used in combination with the first conductive layer 31 which is a conductive reflection layer excellent in the reflectance ratio of from blue to ultraviolet light, in particular, which is not restricted in materials, structures and the like, thus making it possible to improve the light-emitting efficiency of light-emitting elements. In this instance, the support 29 may be joined on the outer surface 32 of the first conductive layer 31.

Of the respective components, the substrate, the semiconductor layers 4 and the conductive layer 12 can be constituted in the same way with similar materials to those shown in FIG. 1. Further, the electrode pad 30, the first conductive layer 31 as a translucent conductive layer and the second conductive layer 33 as a conductive reflection layer can be constituted in the same way with similar materials to those shown in FIG. 14.

The support 29 can also be constituted in the same way with similar materials to those shown in FIG. 14, and particularly preferable when formed of silicon. A dopant may be mixed to impart electrical conductivity to the support 29 formed of silicon.

The first conductive layer 31 is provided in a flat surface form having a through hole, and the outermost surface 5 of the semiconductor layers 4 exposed at the through hole is also allowed to function as a radiating surface 8. In this instance, a decreased transmittance of light by the first conductive layer 31 can be prevented, thereby making it possible to further improve the radiation efficiency of light emitted from the emitting layer 3 and radiated to the outside from the radiating surface 8.

In the light-emitting element, when electricity is allowed to flow between the first and the second conductive layers 31 and 33, hole and electron (or electron and hole) injected into the semiconductor layers 4 from both sides are transported respectively to the second conductive-type semiconductor layer 10 and the first conductive-type semiconductor layer 9 in the thickness direction and recombined in the emitting layer 3, by which gallium nitride compounds constituting the emitting layer 3 are excited to emit light.

Then, light heading from the emitting layer 3 for the outermost surface 5 of the semiconductor layers 4 passes through the second conductive-type semiconductor layer 10 and the first conductive layer 31 which is a translucent conductive layer, and is directly radiated from the radiating surface 8, which is the outer surface 32 of the first conductive layer 31 to the outside of the light-emitting element. Further, light heading from the emitting layer 3 for the first conductive-type semiconductor layer 9 passes through the first conductive-type semiconductor layer 9, and is reflected on the back surface 7 of the semiconductor layers 4, which is a boundary face between the first conductive-type semiconductor layer 9 and the second conductive layer 33 (a conductive reflection layer), and passes through the first conductive-type semiconductor layer 9, the emitting layer 3, the second conductive-type semiconductor layer 10 and the first conductive layer 31, and is radiated from the radiating surface 8 to the outside of the light-emitting element.

In the light-emitting element provided as an example in FIG. 21, an anti-reflection layer may be provided between the outermost surface 5 of the semiconductor layers 4 and the first conductive layer 31 or on the outer surface 32 of the first conductive layer 31. In this instance, the reflectance ratio of light on either of these surfaces is decreased to improve the transmittance, thereby making it possible to prevent the light from being repeatedly reflected in the semiconductor layers 4. Therefore, the radiation efficiency of light emitted from the emitting layer 3 and radiated to the outside from the radiating surface 8 can be further improved.

The anti-reflection layer may be constituted in the same way with similar materials to those shown in FIG. 2. For example, it is preferable that the refractive index of the anti-reflection layer is simply decreased from a surface contacting with the semiconductor layers 4 to a surface contacting with the first conductive layer 31 or from a surface contacting with the first conductive layer 31 to an outer surface which is opposite the foregoing surface. It is also preferable that the thickness of the anti-reflection layer is formed one-quarter of the wavelength of light emitted from the emitting layer 3 in the anti-reflection layer.

For the same purpose with the anti-reflection layer, it is preferable that many projections are formed on the outermost surface 5 of the semiconductor layers 4 or the outer surface of the anti-reflection layer, and the dimension of the projection in the direction intersecting with the height direction is simply decreased from the base of the projection to the apex.

The projections may be constituted similarly to those shown in FIG. 4. For example, the projections may be formed in any given shape such as the conical shape, the pyramid shape, in the conical shape or in the pyramid shape may be formed in a curved shape in which a generatrix constituting the surface is free of flexion points, and a hemispheric shape. Further, it is preferable that the dimension of the base of the projection in the direction intersecting with the height direction is not more than one time the wavelength of light emitted from the emitting layer 3 in the layer on which the projections are formed, and the height of the projection is not less than one time the wavelength.

For the same purpose with the anti-reflection layer, it is preferable that many recesses are formed on the outermost surface 5 of the semiconductor layers 4 or the outer surface of the anti-reflection layer, and the dimension of the recess in the direction intersecting with the depth direction is simply decreased from the opening of the recess to the bottom.

The recesses are constituted similarly to those shown in FIG. 5. For example, the recess may be formed in any given surface such as the conical surface, pyramid surface, in the conical surface or in the pyramid surface may be formed in a curved shape in which a generatrix constituting the surface is free of flexion points, and a hemispheric surface. Further, it is preferable that the dimension of the opening of the recess in the direction intersecting with the depth direction is not more than one time the wavelength of light emitted from the emitting layer in the layer on which the recesses are formed, and the depth of the recess is not less than one time the wavelength.

FIGS. 22 through 26 are sectional views respectively showing steps of manufacturing the light-emitting element shown in FIG. 21 according to the manufacturing method of the present invention.

With reference to FIG. 22, in the manufacturing method of the present invention, gallium nitride compounds are first subjected to epitaxial growth on the surface 2 of the substrate 1, thereby forming semiconductor layers of gallium nitride compounds 4 having a multilayer structure. The method for subjecting the semiconductor layers 4 to epitaxial growth on the substrate 1 is the same as that which has been explained above.

Next, with reference to FIG. 23, the first conductive layer 31 is provided on the outermost surface 5 of the semiconductor layers 4 formed on the surface 2 of the substrate 1 intersecting with the lamination direction by the vacuum deposition method or sputtering method, and an electrode pad 30 is then formed on the outer surface 32 of the first conductive layer 31 thus formed by the vacuum deposition method or sputtering method.

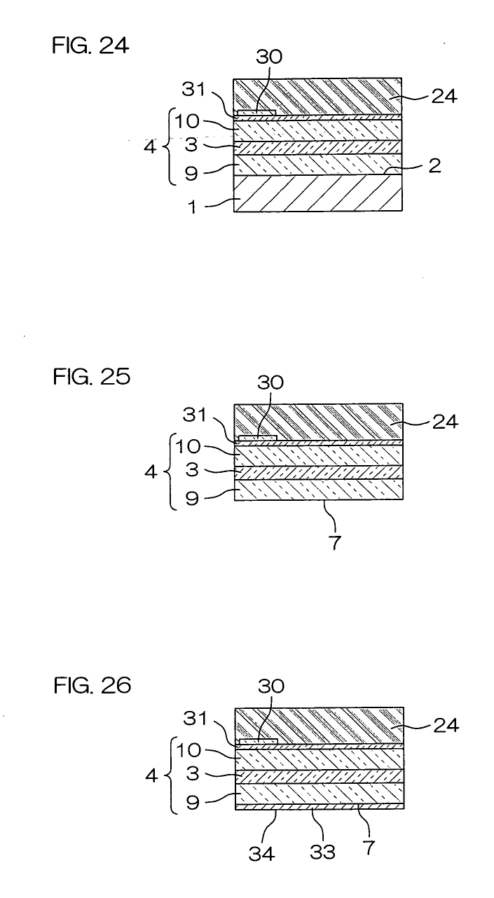

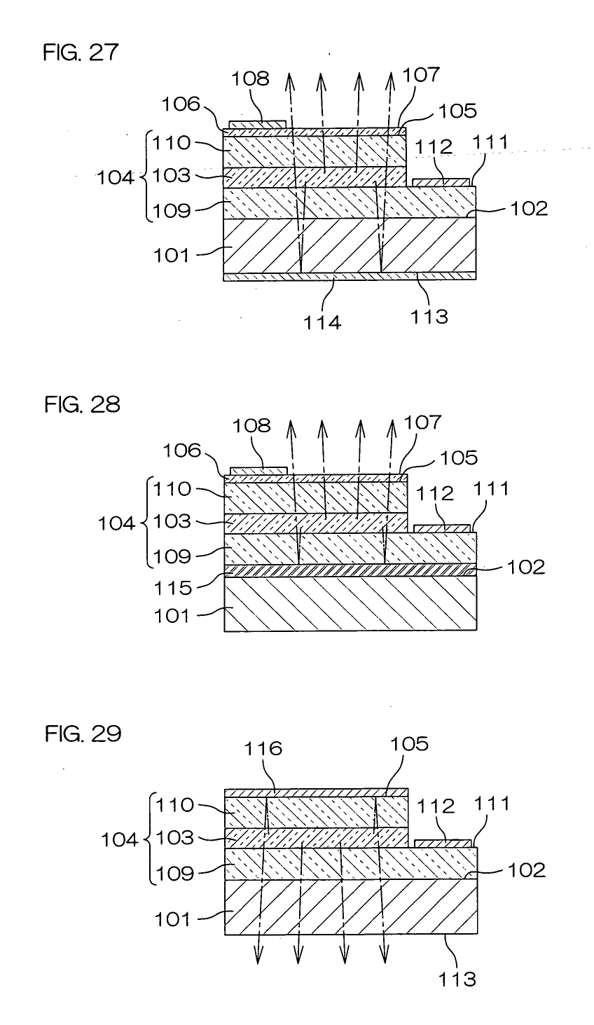

Next, with reference to FIGS. 24 through 26, the semiconductor layers 4, the first conductive layer 31 and the electrode pad 30 are covered with the protective layer 24, the substrate 1 is removed to expose the back surface 7 of the semiconductor layers 4, cleaned by etching, when necessary, and thereafter the second conductive layer 33 is formed on the back surface 7 by the vacuum deposition method or sputtering method.

Thereafter, the support 29 is joined on the outer surface 34 of the second conductive layer 33, and the protective layer 24 is then removed by dry etching, for example, to manufacture the light-emitting element shown in FIG. 21.

According to the manufacturing method of the present invention, the semiconductor layers 4, the first conductive layer 31 and the electrode pad 30 are covered with the protective layer 24 in the step of removing the substrate 1, thereby making it possible to prevent contamination or corrosion of these layers by etching solution and the like for removing the substrate 1. Further, since these layers can be mechanically reinforced by the protective layer 24, they can be prevented from being distorted by stress. Therefore, the manufacturing method of the present invention is able to prevent a reduction in yield due to various defects such as the previously described contamination, corrosion and distortion, thereby manufacturing the light-emitting element more efficiently and at a higher productivity.

In the lighting equipment of the present invention, the light-emitting element of the present invention is constituted in combination with at least either of a fluorescent material or a phosphorescent material. Various fluorescent materials and/or phosphorescent materials which emit any given light in response to illumination of from blue to ultraviolet light having a wavelength of 350 to 400 nm radiated from the radiating surface of the light-emitting element may be used solely or in combination of two or more types of them as the fluorescent material and the phosphorescent material.

In the lighting equipment of the present invention, since the light-emitting element of the present invention is used as a light source, it is excellent in the energy efficiency ratio and able to attain an energy efficiency ratio which is not less than two times as great as that of a fluorescent lamp in particular.

The present invention shall not be restricted to the examples in the figures explained above, but may be modified in various ways within a scope not deviating from the gist of the present invention. For example, the light-emitting element may be reinforced by joining a transparent support capable of transmitting light emitted from the emitting layer 3 to the back surface 7 of the semiconductor layers 4 of the light-emitting element provided as an example in FIG. 1 which is exposed by removal of the substrate 1 or the outer surface 17 of the anti-reflection layer 16 formed on the back surface 7. Further, if the support is joined before removal of the protective layer 24, the semiconductor layers 4 and the anti-reflection layer 16 are protected on removal of the protective layer 24, by which these layers can be prevented from being contaminated or corroded by an etchant for removing the protective layer 24 or from being distorted by stress.

Of the conductive reflection layer 6, the reflection layer 27, the layer which functions as a conductive reflection layer either first or second conductive layers 31, 33 of light-emitting elements shown in the above figures, may be designed so as to transmit light emitted from the emitting layer 3, for example, to an extent of approximately 1%. In this instance, the transmitted light can be monitored for intensity and wavelength to control the emission intensity and the like.

The disclosure of Japanese Patent Application Nos. 2004-249081 and 2004-267995 filed on Aug. 27, 2004 and Sep. 15, 2004 respectively is incorporated herein by reference.

What is claimed is:

1. A light-emitting element comprising;
semiconductor layers of gallium nitride compounds having a multilayer structure including an emitting layer formed by subjecting gallium nitride compounds to epitaxial growth on a substrate;
a conductive reflection layer having electrical conductivity and reflecting light emitted from the emitting layer which is formed on an outermost surface of the semiconductor layers intersecting with the lamination direction in a state of being electrically connected; and
a conductive layer electrically connected to a layer constituting a back surface of the semiconductor layers contacting with the substrate; wherein
the back surface is exposed by removal of the substrate and provided as a light-emitting surface for radiating light emitted from the emitting layer to the outside of the semiconductor layers.

2. A light-emitting element according to claim 1, wherein an anti-reflection layer is formed on the back surface of the semiconductor layers exposed by removal of the substrate.

3. A light-emitting element according to claim 2, wherein the anti-reflection layer is simply decreased in the refractive index from a surface contacting with the semiconductor layers to an outer surface which is opposite the surface.

4. A light-emitting element according to claim 2, wherein the thickness of the anti-reflection layer is formed one-quarter of the wavelength of light emitted from the emitting layer in the anti-reflection layer.

5. A light-emitting element according to claim 1 or 2, wherein many projections are formed on the back surface of the semiconductor layers or the outer surface of the anti-reflection layer formed on the back surface, and the dimension of the projection in the direction intersecting with the height direction is simply decreased from the base of the projection to the apex.

6. A light-emitting element according to claim 5, wherein the dimension of the base of the projection in the direction intersecting with the height direction is not more than one time the wavelength of light emitted from the emitting layer in a layer on which the projections are formed and the height of the projection is not less than one time the wavelength.

7. A light-emitting element according to claim 1 or 2, wherein many recesses are formed on the back surface of the semiconductor layers or the outer surface of the anti-reflection layer formed on the back surface and the dimension of the recess in the direction intersecting with the depth direction is simply decreased from the opening of the recess to the bottom.

8. A light-emitting element according to claim 7, wherein the dimension of the opening of the recess in the direction intersecting with the depth direction is not more than one time the wavelength of light emitted from the emitting layer in a layer on which the recesses are formed and the depth of the recess is not less than one time the wavelength.

9. A light-emitting element according to claim 1, wherein the conductive reflection layer is formed of aluminum or silver.

10. A light-emitting element according to claim 1, wherein a bump electrode is connected to an outer surface which is opposite a surface contacting with the semiconductor layers of the conductive reflection layer.

11. A method for manufacturing the light-emitting element of claim 1, comprising;
a step of forming semiconductor layers by being subjected to epitaxial growth on a substrate;
a step of forming a conductive reflection layer on the outermost surface of the semiconductor layers; and
a step of exposing the back surface of the semiconductor layers by removal of the substrate in a state that the semiconductor layers and the conductive reflection layer are covered with a protective layer.

12. A method for manufacturing the light-emitting element according to claim 11 comprising a step where anti-reflection treatment is provided for the back surface of the semiconductor layers exposed by removal of the substrate.

13. A method for manufacturing the light-emitting element according to claim 11 comprising a step where after formation of the conductive reflection layer, a bump electrode is connected to the outer surface of the conductive reflection layer prior to removal of a substrate, wherein the substrate is removed in a state that the semiconductor layers, the conductive reflection layer and the bump electrode are covered with a protective layer in a step of exposing the back surface of the semiconductor layers by removal of the substrate.

14. A method for manufacturing the light-emitting element according to claim 11 comprising a step where the bump electrode is connected to the outer surface of the conductive reflection layer after the back surface of the semiconductor layers is exposed by removal of the substrate.

15. A method for manufacturing the light-emitting element according to claim 11, wherein the substrate is formed with a boride monocrystal.

16. A method for manufacturing the light-emitting element according to claim 15, wherein boride monocrystal is a monocrystal of zirconium boride or titanium boride.

17. A lighting equipment comprising at least either of a fluorescent material or a phosphorescent material which emits light in response to illumination of light radiated from the light-emitting element of claim 1 and the light-emitting element.

18. A light-emitting element comprising;
semiconductor layers of gallium nitride compounds having a multilayer structure including an emitting layer formed by subjecting gallium nitride compounds to epitaxial growth on a substrate;
a translucent conductive layer having electrical conductivity and transmitting light emitted from the emitting layer which is formed on an outermost surface of the semiconductor layers intersecting with the lamination direction in a state of being electrically connected; and
a conductive layer electrically connected to a layer constituting the back surface of the semiconductor layers contacting with the substrate; wherein
the back surface is exposed by removal of the substrate, a reflection layer for reflecting light emitted from the emitting layer is formed on the exposed back surface, and an outer surface of the translucent conductive layer which is opposite a surface contacting with the semiconductor layers is provided as a radiating surface for radiating light emitted from the emitting layer to the outside of the semiconductor layers.

19. A light-emitting element according to claim 18, wherein the reflection layer is formed of titanium, aluminum or silver.

20. A light-emitting element according to claim 18, wherein a support is joined on the outer surface of the reflection layer.

21. A light-emitting element according to claim 20, wherein the support is formed of silicon.

22. A light-emitting element according to claim 18, wherein an anti-reflection layer is formed between the outermost surface of the semiconductor layers and the translucent conductive layer or on the outer surface of the translucent conductive layer.

23. A light-emitting element according to claim 22, wherein the anti-reflection layer is formed between the outermost surface of the semiconductor layers and the translucent conductive layer, and the refractive index of the anti-reflection layer is simply decreased from a surface contacting with the semiconductor layers to a surface contacting with the translucent conductive layer.

24. A light-emitting element according to claim 22, wherein the anti-reflection layer is formed on the outer surface of the translucent conductive layer, and the refractive index of the anti-reflection layer is simply decreased from a surface contacting with the translucent conductive layer to an outer surface which is opposite the surface.

25. A light-emitting element according to claim 22, wherein the thickness of the anti-reflection layer is formed one-quarter of the wavelength of light emitted from the emitting layer in the anti-reflection layer.

26. A light-emitting element according to claim 18 or 22, wherein many projections are formed on the outermost surface of the semiconductor layers or the outer surface of the anti-reflection layer and the dimension of the projection in the direction intersecting with the height direction is simply decreased from the base of the projection to the apex.

27. A light-emitting element according to claim 26, wherein the dimension of the base of the projection in the direction intersecting with the height direction is not more than one time the wavelength of light emitted from the emitting layer in a layer on which the projections are formed and the height of the projection is not less than one time the wavelength.

28. A light-emitting element according to claim 18 or 22, wherein many recesses are formed on the outermost surface of the semiconductor layers or the outer surface of the anti-reflection layer and the dimension of the recess in the direction intersecting with the depth direction is simply decreased from the opening of the recess to the bottom.

29. A light-emitting element according to claim 28, wherein the dimension of the opening of the recess in the direction intersecting with the depth direction is not more than one time the wavelength of light emitted from the emitting layer in a layer on which the recesses are formed and the depth of the recess is not less than one time the wavelength.

30. A light-emitting element according to claim 18, wherein a translucent conductive layer is formed in a flat surface form having a through hole and the outermost surface of the semiconductor layers exposed at the through hole is also provided as a radiating surface for radiating light emitted from the emitting layer to the outside of the semiconductor layers.

31. A method for manufacturing the light-emitting element of claim 18, comprising;
a step of forming semiconductor layers by being subjected to epitaxial growth on a substrate;
a step of forming a translucent conductive layer on the outermost surface of the semiconductor layers; and
a step of exposing the back surface of the semiconductor layers by removal of the substrate in a state that the semiconductor layers and the translucent conductive layer are covered with a protective layer.

32. A method for manufacturing the light-emitting element according to claim 31, wherein the substrate is formed of boride monocrystal.

33. A method for manufacturing the light-emitting element according to claim 32, wherein boride monocrystal is a monocrystal of zirconium boride or titanium boride.

34. A lighting equipment comprising at least either of a fluorescent material or a phosphorescent material which emits light in response to illumination of light radiated from the light-emitting element of claim 18 and the light-emitting element.

35. A light-emitting element comprising;
semiconductor layers of gallium nitride compounds having a multilayer structure including an emitting layer formed by subjecting gallium nitride compounds to epitaxial growth on a substrate;
a first conductive layer formed on an outermost surface of the semiconductor layers intersecting with the lamination direction in a state of being electrically connected; and
a second conductive layer formed on a back surface of the semiconductor layers exposed by removal of the substrate in a state of being electrically connected; wherein
either of the first or second conductive layer functioning as a conductive reflection layer having electrical conductivity and reflecting light emitted from the emitting layer, and the other layer functioning as a translucent conductive layer having electrical conductivity and transmitting light emitted from the emitting layer, and the outer surface of the translucent conductive layer which is opposite a surface contacting with the semiconductor layers is provided as a radiating surface for radiating light emitted from the emitting layer to the outside of the semiconductor layers.

36. A light-emitting element according to claim 35, wherein the conductive reflection layer is formed of aluminum or silver.

37. A light-emitting element according to claim 35, wherein a support is joined on an outer surface of the conductive reflection layer.

38. A light-emitting element according to claim 37, wherein the support is formed of silicon.

39. A light-emitting element according to claim 35, wherein an anti-reflection layer is provided between a surface of the semiconductor layers in which the translucent conductive layer is formed and the translucent conductive layer or on the outer surface of the translucent conductive layer.

40. A light-emitting element according to claim 39, wherein the anti-reflection layer is formed between a surface of the semiconductor layers in which the translucent conductive layer is formed and the translucent conductive layer and the refractive index of the anti-reflection layer is simply decreased from a surface contacting with the semiconductor layers to a surface contacting with the translucent conductive layer.

41. A light-emitting element according to claim 39, wherein the anti-reflection layer is formed on the outer surface of the translucent conductive layer and the refractive index of the anti-reflection layer is simply decreased from a surface contacting with the translucent conductive layer to an outer surface opposite the surface.

42. A light-emitting element according to claim 39, wherein the thickness of the anti-reflection layer is formed one-quarter of the wavelength of light emitted from the emitting layer in the anti-reflection layer.

43. A light-emitting element according to claim 35 or 39, wherein many projections are formed on the surface of the semiconductor layers in which the translucent conductive layer is formed or an outer surface of the anti-reflection layer and the dimension of the projection in the direction intersecting with the height direction is simply decreased from the base of the projection to the apex.

44. A light-emitting element according to claim 43, wherein the dimension of the base of the projection in the direction intersecting with the height direction is not more than one time the wavelength of light emitted from the emitting layer in a layer on which the projections are formed and the height of the projection is not less than one time the wavelength.

45. A light-emitting element according to claim 35 or 39, wherein many recesses are formed on the surface of the semiconductor layers in which the translucent conductive layer is formed or on an outer surface of the anti-reflection layer, and the dimension of the recess in the direction intersecting with the depth direction is simply decreased from the opening of the recess to the bottom.

46. A light-emitting element according to claim 45, wherein the dimension of the opening of the recess in the direction intersecting with the depth direction is not more than one time the wavelength of light emitted from the emitting layer in a layer on which the recesses are formed, and the depth of the recess is not less than one time the wavelength.

47. A light-emitting element according to claim 35, wherein a translucent conductive layer is formed in a flat surface form having a through hole and the surface of the semiconductor layers exposed at the through hole is also provided as a radiating surface for radiating light emitted from the emitting layer to the outside of the semiconductor layers.

48. A method for manufacturing the light-emitting element of claim 35, comprising;
a step of forming semiconductor layers by being subjected to epitaxial growth on a substrate;
a step of forming a first conductive layer on an outermost surface of the semiconductor layers; and
a step of exposing a back surface of the semiconductor layers by removal of the substrate in a state that the semiconductor layers and the first conductive layer are covered with a protective layer.

49. A method for manufacturing the light-emitting element according to claim 48, wherein the substrate is formed with boride monocrystal.

50. A method for manufacturing the light-emitting element according to claim 48, wherein boride monocrystal is a monocrystal of zirconium boride or titanium boride.

51. A lighting equipment comprising at least either of a fluorescent material or a phosphorescent material which emits light in response to illumination of light radiated from the light-emitting element of claim 35 and the light-emitting element.
